(19) United States
(12) Patent Application Publication
(10) Pub. No.: US 2024/0413251 A1
(43) Pub. Date: Dec. 12, 2024

(54) SEMICONDUCTOR DEVICE AND METHOD FOR FABRICATING THE SAME

(71) Applicant: Samsung Electronics Co., Ltd., Suwon-si (KR)

(72) Inventors: Kyen-Hee LEE, Suwon-si (KR); Jin Myoung LEE, Suwon-si (KR)

(73) Assignee: Samsung Electronics Co., Ltd., Suwon-si (KR)

(21) Appl. No.: 18/539,890

(22) Filed: Dec. 14, 2023

(30) Foreign Application Priority Data
Jun. 9, 2023 (KR) 10-2023-0074150
Oct. 13, 2023 (KR) 10-2023-0136700

(51) Int. Cl. H01L 29/786; H01L 29/423; H01L 29/66; H01L 29/778

(52) U.S. Cl. CPC H01L 29/78696; H01L 29/42356; H01L 29/66545; H01L 29/778

(57) ABSTRACT

A semiconductor device including a substrate including a first region and a second region, a first active pattern extending in a first direction on the first region, a second active pattern extending in the first direction on the second region, a wall structure extending in the first direction between the first region and the second region and separating the first active pattern and the second active pattern from each other, a first gate structure intersecting the first active pattern on the first region, a first two-dimensional (2D) channel layer including a first transition metal dichalcogenide between the first active pattern and the first gate structure, a second gate structure intersecting the second active pattern on the second region, and a second 2D channel layer including a second transition metal dichalcogenide between the second active pattern and the second gate structure may be provided.

### CROSS-REFERENCE TO RELATED APPLICATION

This application claims priority and all the benefit accruing from Korean Patent Application No. 10-2023-0074150 filed on Jun. 9, 2023, in the Korean Intellectual Property Office, the contents of which in its entirety are herein incorporated by reference.

### BACKGROUND

### 1. Technical Field

The present disclosure relates to semiconductor devices and/or methods for fabricating the same, and more particularly, to semiconductor devices using a two-dimensional semiconductor material as a channel and/or methods for fabricating the same.

### 2. Description of the Related Art

As one of the scaling techniques for increasing density of an integrated circuit device, a multi-gate transistor, in which a fin-shaped or nanowire-shaped silicon body is formed on a substrate, and a gate is formed on a surface of the silicon body, has been proposed.

Since such a multi-gate transistor uses a three-dimensional channel, it is easy to perform scaling. In addition, it is possible to improve current control capability even without increasing a length of the gate of the multi-gate transistor. Furthermore, it is possible to effectively suppress a short channel effect (SCE) that a potential of a channel region is affected by a drain voltage.

Meanwhile, as a method for improving performance of a semiconductor device by improving mobility and short channel effect (SCE), a semiconductor device using a two-dimensional semiconductor material as a channel is being studied.

### SUMMARY

Some example embodiments of the present disclosure provide semiconductor devices having improved performance.

Some example embodiments of the present disclosure provide methods for fabricating a semiconductor device having improved performance.

However, example embodiments of the present disclosure are not restricted to those set forth herein. The above and other aspects of the present disclosure will become more apparent to one of ordinary skill in the art to which the present disclosure pertains by referring to the detailed description of the present disclosure given below.

According to an example embodiment of the present inventive concepts, a semiconductor device includes a substrate including a first region and a second region, a first active pattern extending in a first direction on the first region, a second active pattern extending in the first direction on the second region, a wall structure extending in the first direction between the first region and the second region and separating the first active pattern and the second active pattern from each other, a first gate structure intersecting the first active pattern on the first region, a first two-dimensional (2D) channel layer including a first transition metal dichalcogenide between the first active pattern and the first gate structure, a second gate structure intersecting the second active pattern on the second region, and a second 2D channel layer including a second transition metal dichalcogenide between the second active pattern and the second gate structure.

According to an example embodiment of the present inventive concepts, a semiconductor device includes a substrate, a wall structure extending in a first direction on the substrate, a first sheet pattern extending in the first direction on an upper surface of the substrate and a side surface of the wall structure, a second sheet pattern extending in the first direction on an upper surface of the first sheet pattern and the side surface of the wall structure, a seed layer including a transition metal element on the side surface of the wall structure between the first sheet pattern and the second sheet pattern, a two-dimensional (2D) channel layer extending from the seed layer along a surface of the first sheet pattern and a surface of the second sheet pattern, the 2D channel layer including a transition metal dichalcogenide including the transition metal element, and a gate structure intersecting the first sheet pattern and the second sheet pattern and the gate structure on the 2D channel layer.

According to an example embodiment of the present inventive concepts, a semiconductor device includes a substrate including a first region and a second region, a first active pattern including a plurality of first bridge patterns sequentially stacked on the first region, spaced apart from each other, and extending in a first direction, respectively, a second active pattern including a plurality of second bridge patterns sequentially stacked on the second region, spaced apart from each other, and extending in the first direction, respectively, a wall structure extending in the first direction between the first region and the second region and separating the first active pattern and the second active pattern from each other, a first seed layer including an oxide of a transition metal element on a first side surface of the wall structure between each of respective adjacent pairs of the plurality of first bridge patterns, a first two-dimensional (2D) channel layer extending from the first seed layer along a surface of each of the first bridge patterns, the first 2D channel layer including a first transition metal dichalcogenide including the transition metal element, a first gate structure intersecting each of the first bridge patterns and on the first 2D channel layer, a second seed layer including the oxide of the transition metal element on a second side surface of the wall structure between each of respective adjacent pairs of the plurality of second bridge patterns, a second 2D channel layer extending from the second seed layer along a surface of each of the second bridge patterns, the second 2D channel layer including a second transition metal dichalcogenide including the transition metal element, and a second gate structure intersecting each of the second bridge patterns and on the second 2D channel layer.

### BRIEF DESCRIPTION OF THE DRAWINGS

The above and other aspects and features of the present disclosure will become more apparent by describing in detail some example embodiments thereof with reference to the attached drawings, in which:

FIG. 1 is a layout view for describing a semiconductor device according to an example embodiment.

FIG. 2 is a cross-sectional view taken along line A-A of FIG. 1.

FIG. 3 is enlarged views for describing regions R1 and R2 of FIG. 2.

FIG. 4 is a cross-sectional view taken along line B-B of FIG. 1.

FIG. 5 is a cross-sectional view taken along line C-C of FIG. 1.

FIGS. 6 to 10 are various enlarged views for describing regions R1 and R2 of FIG. 2, according to some example embodiments.

FIGS. 11 and 12 are other various cross-sectional views for describing a semiconductor device according to some example embodiments.

FIGS. 13 to 43 are intermediate step views for describing a method for fabricating a semiconductor device according to an example embodiment.

### DETAILED DESCRIPTION

Terms “first”, “second” and the like are used herein to describe various elements or components, but these elements or components are not limited by these terms. These terms are used only to distinguish one element or component from another element or component. Therefore, a first element or component mentioned below may be a second element or component within the technical spirit of the present disclosure.

In addition, in the present specification, the term “same” refers to the meaning including not only the completely same, but also a fine difference that may occur due to a margin in a process or the like.

In other words, while the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., +10%).

When the terms “about” or “substantially” are used in this specification in connection with a numerical value, it is intended that the associated numerical value includes a manufacturing or operational tolerance (e.g., +10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

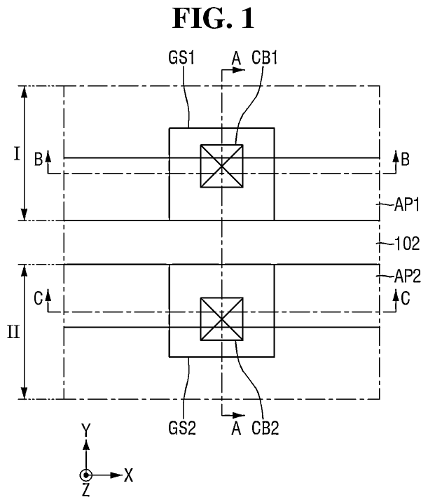

Hereinafter, a semiconductor device according to some example embodiments will be described with reference to FIGS. 1 to 12.

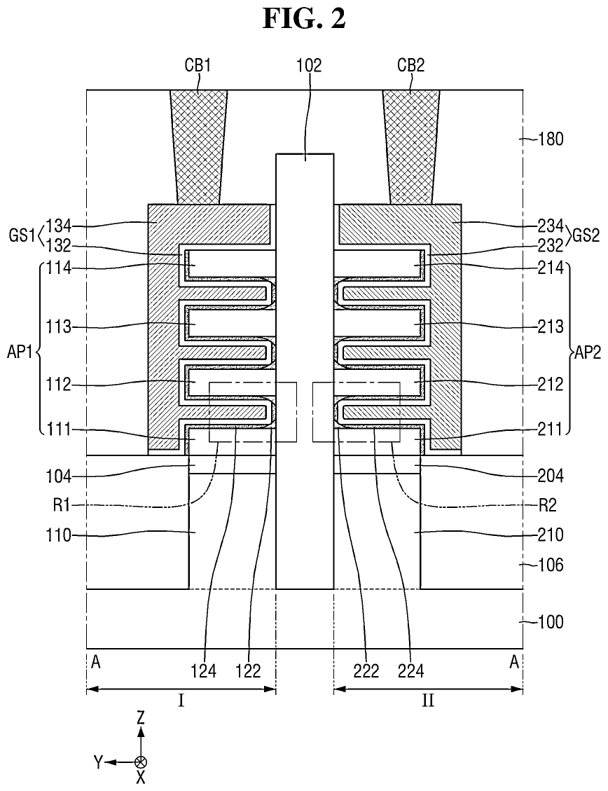

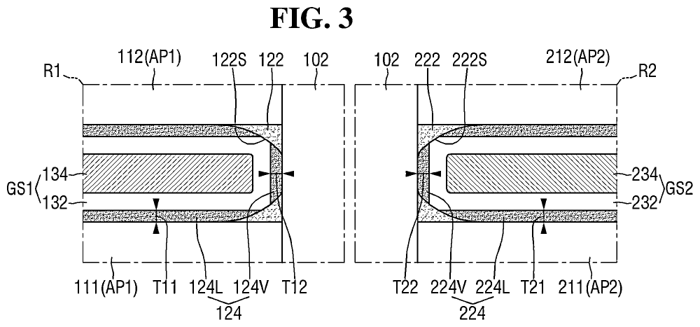

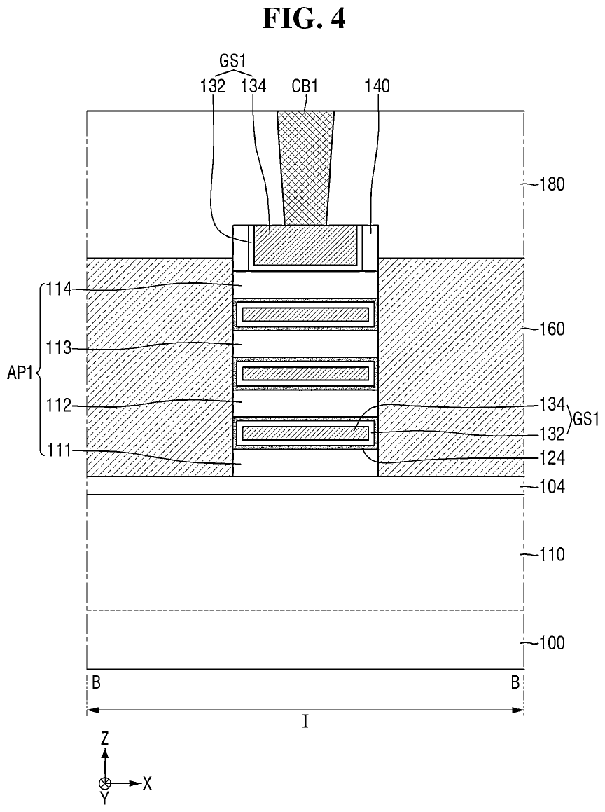

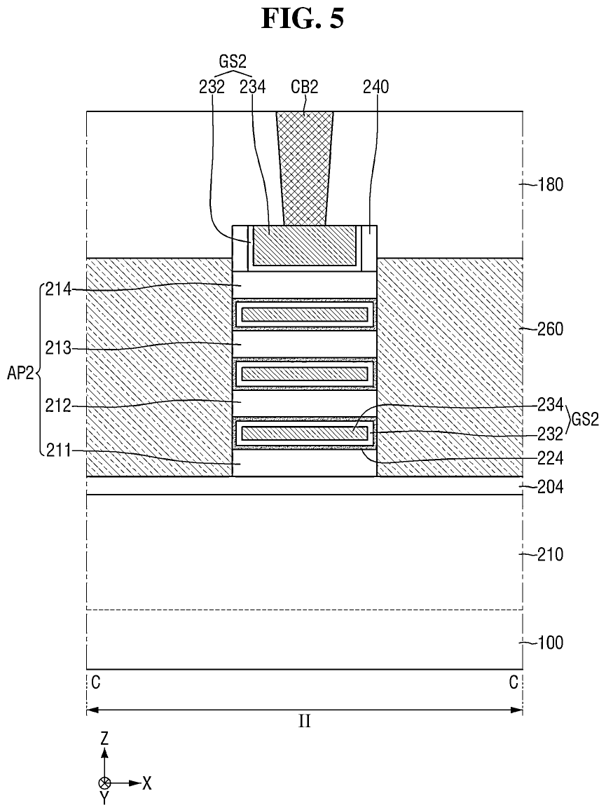

FIG. 1 is a layout view for describing a semiconductor device according to an example embodiment. FIG. 2 is a cross-sectional view taken along line A-A of FIG. 1. FIG. 3 is enlarged views for describing regions R1 and R2 of FIG. 2. FIG. 4 is a cross-sectional view taken along line B-B of FIG. 1. FIG. 5 is a cross-sectional view taken along line C-C of FIG. 1.

Referring to FIGS. 1 to 5, a semiconductor device according to an example embodiment may include a substrate 100, a first active pattern AP1, a second active pattern AP2, a first insulating pattern 104, a second insulating pattern 204, a field insulating film 106, a wall structure 102, a first seed layer 122, a second seed layer 222, a first two-dimensional (2D) channel layer 124, a second 2D channel layer 224, a first gate structure GS1, a second gate structure GS2, a first gate spacer 140, a second gate spacer 240, a first source/drain pattern 160, a second source/drain pattern 260, an interlayer insulating film 180, a first gate contact CB1, and a second gate contact CB2.

A substrate 100 may be bulk silicon or silicon-on-insulator (SOI). Unlike this, the substrate 100 may also be a silicon substrate, or may also include another material, for example, silicon germanium, silicon germanium on insulator (SGOI), indium antimonide, a lead tellurium compound, indium arsenide, indium phosphide, gallium arsenide, or gallium antimonide. In some example embodiments, the substrate 100 may also have an epitaxial layer formed on a base substrate. For convenience of explanation, in the following description, the substrate 100 will be described as a silicon substrate.

The substrate 100 may include a first region I and a second region II. The first region I and the second region II may be regions separated from each other around a wall structure 102 described later. For example, the wall structure 102 may extend in a first direction X parallel to an upper surface of the substrate 100, and the first region I and the second region II may be arranged along a second direction Y intersecting the first direction X with the wall structure 102 as the center. That is, the first region I may be a region of the substrate 100 defined on one side of the wall structure 102, and the second region II may be a region of the substrate 100 defined on the other side of the wall structure 102.

In some example embodiments, transistors of different conductivity types may be formed in the first region I and the second region II, respectively. As an example, the first region I may be an NFET region, and the second region II may be a PFET region. As another example, the first region I may be a PFET region, and the second region II may be an NFET region. However, the inventive concepts of the present disclosure are not limited thereto, and transistors of the same conductivity type may be formed in the first region I and the second region II.

The first active pattern AP1 may be formed on the first region I of the substrate 100. The first active pattern AP1 may extend in the first direction X. The first active pattern AP1 may include a plurality of first bridge patterns (e.g., first to fourth sheet patterns 111 to 114) that are sequentially stacked on the upper surface of the substrate 100 and are spaced apart from each other to each extend in the first direction X. The first active pattern AP1 may be provided as a channel region of a multibridge-channel metal-oxide-semiconductor field-effect transistor (MBCFET®) including a multi-bridge channel. Although four bridge patterns are illustrated as being included in the first active pattern AP1, this is only an example, and the number of bridge patterns included in the first active pattern AP1 is not limited thereto.

In some example embodiments, a first fin pattern 110 may be formed between the substrate 100 and the first active pattern AP1. The first fin pattern 110 may protrude from the upper surface of the substrate 100 and extend in the first direction X. The first fin pattern 110 may also be formed by etching a portion of the substrate 100 or may also be an epitaxial layer grown from the substrate 100. The first bridge patterns 111 to 114 may be sequentially stacked on an upper surface of the first fin pattern 110.

The second active pattern AP2 may be formed on the second region II of the substrate 100. The second active pattern AP2 may extend in the first direction X. The second active pattern AP2 may include a plurality of second bridge patterns (e.g., fifth to eighth sheet patterns 211 to 214) that are sequentially stacked on the upper surface of the substrate 100 and are spaced apart from each other to each extend in the first direction X. The second active pattern AP2 may be provided as a channel region of an MBCFET® including a multi-bridge channel. Although four bridge patterns are illustrated as being included in the second active pattern AP2, this is only an example, and the number of bridge patterns included in the second active pattern AP2 is not limited to that illustrated.

In some example embodiments, a second fin pattern 210 may be formed between the substrate 100 and the second active pattern AP2. The second fin pattern 210 may protrude from the upper surface of the substrate 100 and extend in the first direction X. The second fin pattern 210 may also be formed by etching a portion of the substrate 100 or may also be an epitaxial layer grown from the substrate 100. The second bridge patterns 211 to 214 may be sequentially stacked on an upper surface of the second fin pattern 210.

It is only illustrated in FIG. 2 that a width of the first active pattern AP1 and/or a width of the second active pattern AP2 may be constant in a vertical direction (e.g., a third direction Z) intersecting the upper surface of the substrate 100, but this is only an example. Depending on the characteristics of an etching process (or patterning process) for forming the first active pattern AP1 and the second active pattern AP2, the width of the first active pattern AP1 and/or the width of the second active pattern AP2 may decrease as a distance from the substrate 100 increases.

Each of the first active pattern AP1 and the second active pattern AP2 may include silicon (Si) or germanium (Ge), which is an elemental semiconductor material. In some example embodiments, each of the first active pattern AP1 and the second active pattern AP2 may include a compound semiconductor, for example, a group IV-IV compound semiconductor or a group III-V compound semiconductor. The group IV-IV compound semiconductor may be, for example, a binary compound or a ternary compound including at least two or more of carbon (C), silicon (Si), germanium (Ge), and tin (Sn), or a compound obtained by doping carbon (C), silicon (Si), germanium (Ge), and tin (Sn) with a group IV element. The group III-V compound semiconductor may be, for example, one of a binary compound, a ternary compound, or a quaternary compound formed by combining at least one of aluminum (Al), gallium (Ga), or indium (In), which are group III elements, and at least one of phosphorus (P), arsenic (As), or antimony (Sb), which are group V elements. For convenience of explanation, in the following description, the first active pattern AP1 and the second active pattern AP2 will each be described as a silicon (Si) pattern.

In some example embodiments, the first active pattern AP1 and the second active pattern AP2 may be disposed on the same level as each other. Here, being disposed on the same level means being disposed at the same height as each other with respect to the upper surface of the substrate 100. For example, as illustrated, each of the first bridge patterns 111 to 114 and a corresponding one of the second bridge patterns 211 to 214 may be disposed at the same height.

In some example embodiments, the first active pattern AP1 and the second active pattern AP2 may be formed at the same level as each other. In this specification, being formed at the same level means being formed by the same fabricating process. For example, the first active pattern AP1 and the second active pattern AP2 may be made of the same material and/or the same material composition.

The first insulating pattern 104 may be interposed between the substrate 100 and the first active pattern AP1. For example, the first insulating pattern 104 may be interposed between the first fin pattern 110 and the bridge pattern (e.g., the first sheet pattern 111) disposed at the lowermost portion among the first bridge patterns 111 to 114. The first insulating pattern 104 may extend in the first direction X. The first active pattern AP1 may be electrically separated from the substrate 100 and/or the first fin pattern 110 by the first insulating pattern 104.

The second insulating pattern 204 may be interposed between the substrate 100 and the second active pattern AP2. For example, the second insulating pattern 204 may be interposed between the second fin pattern 210 and the bridge pattern (e.g., the fifth sheet pattern 211) disposed at the lowermost portion among the second bridge patterns 211 to 214. The second insulating pattern 204 may extend in the first direction X. The second active pattern AP2 may be electrically separated from the substrate 100 and/or the second fin pattern 210 by the second insulating pattern 204.

Each of the first insulating pattern 104 and the second insulating pattern 204 may include, for example, at least one of silicon oxide, silicon nitride, silicon oxynitride, or a combination thereof, but is not limited thereto. For example, each of the first insulating pattern 104 and the second insulating pattern 204 may include a silicon nitride film.

In some example embodiments, the first insulating pattern 104 and the second insulating pattern 204 may be disposed on the same level as each other. In some example embodiments, the first insulating pattern 104 and the second insulating pattern 204 may be formed at the same level as each other.

A field insulating film 106 may be formed on the substrate 100. The field insulating film 106 may include, for example, at least one of silicon oxide, silicon nitride, silicon oxynitride, or a combination thereof, but example embodiments are not limited thereto. As an example, the field insulating film 106 may include a silicon oxide film.

In some example embodiments, the field insulating film 106 may cover at least a portion of a side surface of the first fin pattern 110 and at least a portion of a side surface of the second fin pattern 210. It is only illustrated in FIG. 2 that an upper surface of the field insulating film 106 is disposed on the same plane as an upper surface of the first insulating pattern 104 and an upper surface of the second insulating pattern 204, but this is only an example. According to some example embodiments, the top surface of the field insulating film 106 may also be formed to be lower than the upper surface of the first insulating pattern 104 and the upper surface of the second insulating pattern 204, and may also be formed to be higher than the upper surface of the first insulating pattern 104 and the upper surface of the second insulating pattern 204.

The wall structure 102 may be interposed between the first region I and the second region II. The wall structure 102 may extend in the first direction X to separate the first active pattern AP1 and the second active pattern AP2. For example, the wall structure 102 may include first and second side surfaces that intersect the second direction Y and are opposite to each other. The first active pattern AP1 may extend in the first direction X on the first side surface of the wall structure 102, and the second active pattern AP2 may extend in the first direction X on the second side surface of the wall structure 102. In some example embodiments, the first active pattern AP1 may be in contact with the first side surface of the wall structure 102, and the second active pattern AP2 may be in contact with the second side surface of the wall structure 102. The first active pattern AP1 and the second active pattern AP2 separated by the wall structure 102 may be provided as a channel region of a forksheet field effect transistor (forksheet FET).

The wall structure 102 may include, for example, at least one of silicon oxide, silicon nitride, silicon oxynitride, or a combination thereof, but example embodiments are not limited thereto. As an example, the wall structure 102 may include a silicon nitride film. Such a wall structure 102 may be provided as an insulating wall (so-called dielectric wall scheme (DWS)) in the forksheet field effect transistor.

It is only illustrated in FIG. 2 that a width of the wall structure 102 is constant in the vertical direction (e.g., the third direction Z), but this is only an example. Depending on the characteristics of an etching process (or patterning process) for forming the wall structure 102, the width of the wall structure 102 may increase as a distance from the substrate 100 increases.

It is only illustrated that a lower surface of the wall structure 102 is disposed on the same plane as the upper surface of the substrate 100, but this is only an example. As another example, the lower surface of the wall structure 102 may also be formed to be lower than the upper surface of the substrate 100, or may also be formed to be higher than the upper surface of the substrate 100. In some example embodiments, the wall structure 102 may extend in the first direction X to separate the first insulating pattern 104 and the second insulating pattern 204. For example, the lower surface of the wall structure 102 may be formed to be lower than a lower surface of the first insulating pattern 104 and a lower surface of the second insulating pattern 204.

A first seed layer 122 may be formed on a side surface of the wall structure 102 between the first bridge patterns 111 to 114. As an example, as illustrated in FIG. 3, the first seed layer 122 may be formed on a first portion of the side surface of the wall structure 102 that is adjacent to an upper surface of the first sheet pattern 111 and a second portion of the side surface of the wall structure 102 that is adjacent to a lower surface of the second sheet pattern 112.

The first seed layer 122 may include a first surface 122S. The first surface 122S is a surface of the first seed layer 122 exposed from the first active pattern AP1 and the wall structure 102 (not in contact with the first active pattern AP1 and the wall structure 102). In some example embodiments, the first surface 122S may include a concave curved surface. This may be due to characteristics of an etching process for forming the first seed layer 122.

In some example embodiments, the first seed layer 122 may expose a portion of the side surface of the wall structure 102 between each of respective adjacent pairs of the first bridge patterns 111 to 114. As an example, the first seed layer 122 adjacent to the upper surface of the first sheet pattern 111 and the first seed layer 122 adjacent to the lower surface of the second sheet pattern 112 may be spaced apart from each other in the third direction Z.

A second seed layer 222 may be formed on a side surface of the wall structure 102 between the second bridge patterns 211 to 214. As an example, as illustrated in FIG. 3, the second seed layer 222 may be formed on a first portion of the side surface of the wall structure 102 that is adjacent to an upper surface of the fifth sheet pattern 211 and a second portion of the side surface of the wall structure 102 that is adjacent to a lower surface of the sixth sheet pattern 212.

The second seed layer 222 may include a second surface 222S. The second surface 222S is a surface of the second seed layer 222 exposed from the second active pattern AP2 and the wall structure 102 (not in contact with the second active pattern AP2 and the wall structure 102). In some example embodiments, the second surface 222S may include a concave curved surface. This may be due to characteristics of an etching process for forming the second seed layer 222.

In some example embodiments, the second seed layer 222 may expose a portion of the side surface of the wall structure 102 between each of respective adjacent pairs of the second bridge patterns 211 to 214. As an example, the second seed layer 222 adjacent to the upper surface of the fifth sheet pattern 211 and the second seed layer 222 adjacent to the lower surface of the sixth sheet pattern 212 may be spaced apart from each other in the third direction Z.

Each of the first seed layer 122 and the second seed layer 222 may include a transition metal element. The transition metal element may include, for example, at least one metal element of molybdenum (Mo), tungsten (W), niobium (Nb) vanadium (V), tantalum (Ta), titanium (Ti), zirconium (Zr), hafnium (Hf), technetium (Tc), rhenium (Re), or copper (Cu). In some example embodiments, the first seed layer 122 and the second seed layer 222 may include the same transition metal element. As an example, both the first seed layer 122 and the second seed layer 222 may include molybdenum (Mo). As another example, both the first seed layer 122 and the second seed layer 222 may include tungsten (W).

In some example embodiments, each of the first seed layer 122 and the second seed layer 222 may include an oxide of the transition metal element. As an example, each of the first seed layer 122 and the second seed layer 222 may include molybdenum dioxide (MoO₂). As another example, each of the first seed layer 122 and the second seed layer 222 may include tungsten dioxide (WO₂).

A first 2D channel layer 124 may extend from the first seed layer 122 along the surface of the first active pattern AP1. As an example, as illustrated in FIG. 3, the first 2D channel layer 124 may extend along the upper surface of the first sheet pattern 111 from the first seed layer 122 adjacent to the upper surface of the first sheet pattern 111, and may extend along the lower surface of the second sheet pattern 112 from the first seed layer 122 adjacent to the lower surface of the second sheet pattern 112.

The first 2D channel layer 124 may surround at least a portion of a circumference of each of the first bridge patterns 111 to 114 exposed from the wall structure 102 and/or the first insulating pattern 104. In some example embodiments, the first 2D channel layer 124 may not extend along an upper surface of the uppermost bridge pattern (e.g., the fourth sheet pattern 114) among the first bridge patterns 111 to 114. As an example, as illustrated in FIG. 2, the first 2D channel layer 124 may extend along side and upper surfaces of the first sheet pattern 111, lower, side, and upper surfaces of the second sheet pattern 112, lower, side, and upper surfaces of the third sheet pattern 113, and lower and side surfaces of the fourth sheet pattern 114.

The first 2D channel layer 124 may include a first transition metal dichalcogenide including the transition metal element of the first seed layer 122. For example, the first transition metal dichalcogenide may include one transition metal element of molybdenum (Mo), tungsten (W), niobium (Nb) vanadium (V), tantalum (Ta), titanium (Ti), zirconium (Zr), hafnium (Hf), technetium (Tc), rhenium (Re), and copper (Cu), and one chalcogen element of sulfur(S), selenium (Se), and tellurium (Te). As an example, when the first seed layer 122 includes molybdenum dioxide (MoO₂), the first 2D channel layer 124 may include molybdenum disulfide (MoS₂). As another example, when the first seed layer 122 includes tungsten dioxide (WO₂), the first 2D channel layer 124 may include tungsten disulfide (WS₂).

The first 2D channel layer 124 may be formed by a crystal growth method using the first seed layer 122 as a seed layer. For example, the first 2D channel layer 124 may be formed by two-dimensionally growing crystals from the first surface 122S of the first seed layer 122. In some example embodiments, the first 2D channel layer 124 may have a single crystal structure. In some example embodiments, the first 2D channel layer 124 may expose a portion of the first surface 122S.

In some example embodiments, the first 2D channel layer 124 may be formed by two-dimensionally growing crystals to have a thickness of several nanometers (nm). For example, the thickness (e.g., T11 and T12 in FIG. 3) of the first 2D channel layer 124 may be about 10 nm or less.

In some example embodiments, a portion of the first 2D channel layer 124 may extend along the side surface of the wall structure 102 between each of respective adjacent pairs of the first bridge patterns 111 to 114. For example, as illustrated in FIG. 3, the first 2D channel layer 124 may include a first horizontal portion 124L and a first vertical portion 124V. The first horizontal portion 124L may extend from the first seed layer 122 in a horizontal direction (e.g., in the first direction X and/or in the second direction Y) along the surface of the first active pattern AP1. The first vertical portion 124V may extend from the first seed layer 122 in a vertical direction (e.g., in the third direction Z) along the side surface of the wall structure 102.

It is only illustrated that the thickness T11 of the first horizontal portion 124L and the thickness T12 of the first vertical portion 124V are the same as each other, but this is only an example, and depending on conditions of the crystal growth method, the thickness T11 of the first horizontal portion 124L and the thickness T12 of the first vertical portion 124V may be different from each other.

A second 2D channel layer 224 may extend from the second seed layer 222 along the surface of the second active pattern AP2. As an example, as illustrated in FIG. 3, the second 2D channel layer 224 may extend along the upper surface of the fifth sheet pattern 211 from the second seed layer 222 adjacent to the upper surface of the fifth sheet pattern 211, and may extend along the lower surface of the sixth sheet pattern 212 from the second seed layer 222 adjacent to the lower surface of the sixth sheet pattern 212.

The second 2D channel layer 224 may surround at least a portion of a circumference of each of the second bridge patterns 211 to 214 exposed from the wall structure 102 and/or the second insulating pattern 204. In some example embodiments, the second 2D channel layer 224 may not extend along an upper surface of the uppermost bridge pattern (e.g., the eighth sheet pattern 214) among the second bridge patterns 211 to 214. As an example, as illustrated in FIG. 2, the second 2D channel layer 224 may extend along side and upper surfaces of the fifth sheet pattern 211, lower, side, and upper surfaces of the sixth sheet pattern 212, lower, side, and upper surfaces of the seventh sheet pattern 213, and lower and side surfaces of the eighth sheet pattern 214.

The second 2D channel layer 224 may include a second transition metal dichalcogenide including the transition metal element of the second seed layer 222. For example, the second transition metal dichalcogenide may include one transition metal element of molybdenum (Mo), tungsten (W), niobium (Nb) vanadium (V), tantalum (Ta), titanium (Ti), zirconium (Zr), hafnium (Hf), technetium (Tc), rhenium (Re), and copper (Cu), and one chalcogen element of sulfur(S), selenium (Se), and tellurium (Te). As an example, when the second seed layer 222 includes molybdenum dioxide (MoO₂), the second 2D channel layer 224 may include molybdenum disulfide (MoS₂). As another example, when the second seed layer 222 includes tungsten dioxide (WO₂), the second 2D channel layer 224 may include tungsten disulfide (WS₂).

The second 2D channel layer 224 may be formed by a crystal growth method using the second seed layer 222 as a seed layer. For example, the second 2D channel layer 224 may be formed by two-dimensionally growing crystals from the second surface 222S of the second seed layer 222. In some example embodiments, the second 2D channel layer 224 may have a single crystal structure. In some example embodiments, the second 2D channel layer 224 may expose a portion of the second surface 222S.

In some example embodiments, the second 2D channel layer 224 may be formed by two-dimensionally growing crystals to have a thickness of several nanometers (nm). For example, the thickness (e.g., T11 and T12 in FIG. 3) of the second 2D channel layer 224 may be about 10 nm or less.

In some example embodiments, a portion of the second 2D channel layer 224 may extend along the side surface of the wall structure 102 between each of respective pairs of the second bridge patterns 211 to 214. For example, as illustrated in FIG. 3, the second 2D channel layer 224 may include a second horizontal portion 224L and a second vertical portion 224V. The second horizontal portion 224L may extend from the second seed layer 222 in a horizontal direction (e.g., in the first direction X and/or in the second direction Y) along the surface of the second active pattern AP2. The second vertical portion 224V may extend from the second seed layer 222 in a vertical direction (e.g., in the third direction Z) along the side surface of the wall structure 102.

It is only illustrated that the thickness T21 of the second horizontal portion 224L and the thickness T22 of the second vertical portion 224V are the same as each other, but this is only an example, and depending on conditions of the crystal growth method, the thickness T21 of the second horizontal portion 224L and the thickness T22 of the second vertical portion 224V may be different from each other.

In some example embodiments, the first transition metal dichalcogenide of the first 2D channel layer 124 and the second transition metal dichalcogenide of the second 2D channel layer 224 may be the same as each other. As an example, both the first 2D channel layer 124 and the second 2D channel layer 224 may include molybdenum disulfide (MoS₂). As another example, both the first 2D channel layer 124 and the second 2D channel layer 224 may include tungsten disulfide (WS₂).

However, the example embodiments of the present disclosure are not limited thereto, and the first transition metal dichalcogenide of the first 2D channel layer 124 and the second transition metal dichalcogenide of the second 2D channel layer 224 may also be different from each other. As an example, when the first seed layer 122 and the second seed layer 222 include molybdenum dioxide (MoO₂), the first 2D channel layer 124 may include molybdenum disulfide (MoS₂), and the second 2D channel layer 224 may include molybdenum diselenide (MoSe₂). As another example, when the first seed layer 122 and the second seed layer 222 include tungsten dioxide (WO₂), the first 2D channel layer 124 may include tungsten disulfide (WS₂), and the second 2D channel layer 224 may include tungsten diselenide (WSe₂).

The first gate structure GS1 may be formed on the first region I of the substrate 100. The first gate structure GS1 may intersect the first active pattern AP1. For example, the first gate structure GS1 may extend in the second direction Y on the first side surface of the wall structure 102. Each of the first bridge patterns 111 to 114 may extend in the first direction X and penetrate through the first gate structure GS1. Accordingly, the first gate structure GS1 may surround a circumference of each of the first bridge patterns 111 to 114 exposed from the wall structure 102 and/or the first insulating pattern 104.

The second gate structure GS2 may be formed on the second region II of the substrate 100. The second gate structure GS2 may intersect the second active pattern AP2. For example, the second gate structure GS2 may extend in the second direction Y on the second side surface of the wall structure 102. Each of the second bridge patterns 211 to 214 may extend in the first direction X and penetrate through the second gate structure GS2. Accordingly, the second gate structure GS2 may surround a circumference of each of the second bridge patterns 211 to 214 exposed from the wall structure 102 and/or the second insulating pattern 204.

The first gate structure GS1 may include a first gate dielectric film 132 and a first gate electrode 134, and the second gate structure GS2 may include a second gate dielectric film 232 and a second gate electrode 234.

The first gate dielectric film 132 may be stacked on the first 2D channel layer 124. The first 2D channel layer 124 may be interposed between the first active pattern AP1 and the first gate dielectric film 132. The first gate dielectric film 132 may surround a circumference of the first active pattern AP1. When the first 2D channel layer 124 does not extend along the upper surface of the uppermost bridge pattern (e.g., the fourth sheet pattern 114), the first gate dielectric film 132 may be in contact with the upper surface of the uppermost bridge pattern (e.g., the fourth sheet pattern 114). In some example embodiments, the first gate dielectric film 132 may further extend along the upper surface of the field insulating film 106 and the side surface of the wall structure 102.

The second gate dielectric film 232 may be stacked on the second 2D channel layer 224. The second 2D channel layer 224 may be interposed between the second active pattern AP2 and the second gate dielectric film 232. The second gate dielectric film 232 may surround a circumference of the second active pattern AP2. When the second 2D channel layer 224 does not extend along the upper surface of the uppermost bridge pattern (e.g., the eighth sheet pattern 214), the second gate dielectric film 232 may be in contact with the upper surface of the uppermost bridge pattern (e.g., the eighth sheet pattern 214). In some example embodiments, the second gate dielectric film 232 may further extend along the upper surface of the field insulating film 106 and the side surface of the wall structure 102.

Each of the first gate dielectric film 132 and the second gate dielectric film 232 may include, for example, at least one of silicon oxide, silicon oxynitride, silicon nitride, or a high-k material having a dielectric constant greater than that of silicon oxide. The high-k material may include, for example, at least one of hafnium oxide (HfO₂), zirconium oxide (ZrO₂), lanthanum oxide (La₂O₃), aluminum oxide (Al₂O₃), titanium oxide (TiO₂), strontium titanium oxide (SrTiO₃), lanthanum aluminum oxide (LaAlO₃), yttrium oxide (Y₂O₃), hafnium oxynitride (HfOₓN_{y}), zirconium oxynitride (ZrOₓN_{y}), lanthanum oxynitride (La₂OₓN_{y}), aluminum oxynitride (Al₂OₓN_{y}), titanium oxynitride (TiOₓN_{y}), strontium titanium oxynitride (SrTiOₓN_{y}), lanthanum aluminum oxynitride (LaAlOₓN_{y}), yttrium oxynitride (Y₂OₓN_{y}), or a combination thereof, but example embodiments are not limited thereto.

The semiconductor device according to some example embodiments may include a negative capacitance (NC) FET using a negative capacitor. For example, the first gate dielectric film 132 and/or the second gate dielectric film 232 may include a ferroelectric material film having ferroelectric characteristics and a paraelectric material film having paraelectric characteristics.

The ferroelectric material film may have a negative capacitance, and the paraelectric material film may have a positive capacitance. For example, when two or more capacitors are connected in series with each other and the capacitance of each capacitor has a positive value, a total capacitance decreases as compared with a capacitance of each individual capacitor. On the other hand, when at least one of the capacitances of two or more capacitors connected in series with each other has a negative value, the total capacitance may be greater than an absolute value of each individual capacitance while having a positive value.

When the ferroelectric material film having the negative capacitance and the paraelectric material film having the positive capacitance are connected in series with each other, a total capacitance value of the ferroelectric material film and the paraelectric material film connected in series with each other may increase. A transistor including the ferroelectric material film may have a subthreshold swing (SS) less than 60 mV/decade at room temperature, using the increase in the total capacitance value.

The ferroelectric material film may have the ferroelectric characteristics. The ferroelectric material film may include, for example, at least one of hafnium oxide, hafnium zirconium oxide, barium strontium titanium oxide, barium titanium oxide, or lead zirconium titanium oxide. Here, as an example, the hafnium zirconium oxide may be a material obtained by doping hafnium oxide with zirconium (Zr). As another example, the hafnium zirconium oxide may also be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce)), dysprosium (Dy), erbium (Er), gadolinium (Gd), germanium (Ge), scandium (Sc), strontium (Sr), or tin (Sn). A type of dopant included in the ferroelectric material film may vary depending on a type of ferroelectric material included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), or yttrium (Y).

When the dopant is aluminum (Al), the ferroelectric material film may include about 3 to about 8 atomic % (at %) of aluminum. Here, a ratio of the dopant may be a ratio of aluminum to the sum of hafnium and aluminum.

When the dopant is silicon (Si), the ferroelectric material film may include about 2 to about 10 atomic % (at %) of silicon. When the dopant is yttrium (Y), the ferroelectric material film may include about 2 to about 10 at % of yttrium. When the dopant is gadolinium (Gd), the ferroelectric material film may include about 1 to about 7 at % of gadolinium. When the dopant is zirconium (Zr), the ferroelectric material film may include about 50 to about 80 at % of zirconium.

The paraelectric material film may have the paraelectric characteristics. The paraelectric material film may include, for example, at least one of silicon oxide or metal oxide having a high dielectric constant. The metal oxide included in the paraelectric material film may include, for example, at least one of hafnium oxide, zirconium oxide, or aluminum oxide, but example embodiments are not limited thereto.

The ferroelectric material film and the paraelectric material film may include the same material. The ferroelectric material film may have the ferroelectric characteristics, but the paraelectric material film may not have the ferroelectric characteristics. For example, when the ferroelectric material film and the paraelectric material film include hafnium oxide, a crystal structure of the hafnium oxide included in the ferroelectric material film is different from a crystal structure of the hafnium oxide included in the paraelectric material film.

The ferroelectric material film may have a thickness having the ferroelectric characteristics. The thickness of the ferroelectric material film may be, for example, about 0.5 to about 10 nm, but is not limited thereto. Because a critical thickness representing the ferroelectric characteristics may vary for each ferroelectric material, the thickness of the ferroelectric material film may vary depending on the ferroelectric material.

As an example, the first gate dielectric film 132 and/or the second gate dielectric film 232 may include one ferroelectric material film. As another example, the first gate dielectric film 132 and/or the second gate dielectric film 232 may include a plurality of ferroelectric material films spaced apart from each other. The first gate dielectric film 132 and/or the second gate dielectric film 232 may have a stacked film structure in which a plurality of ferroelectric material films and a plurality of paraelectric material films are alternately stacked.

The first gate electrode 134 may be stacked on the first gate dielectric film 132. The first gate dielectric film 132 may be interposed between the first active pattern AP1 and the first gate electrode 134.

The second gate electrode 234 may be stacked on the second gate dielectric film 232. The second gate dielectric film 232 may be interposed between the second active pattern AP2 and the second gate electrode 234.

Each of the first gate electrode 134 and the second gate electrode 234 may be formed by, for example, a replacement process, but example embodiments are not limited thereto. It is only illustrated that each of the first gate electrode 134 and the second gate electrode 234 is a single film, but this is only an example. In some example embodiments, each of the first gate electrode 134 and the second gate electrode 234 may be formed by stacking a plurality of conductive layers.

In some example embodiments, the wall structure 102 may extend in the first direction X to separate the first gate structure GS1 and the second gate structure GS2 from each other. For example, the upper surface of the wall structure 102 may be formed to be higher than an upper surface of the first gate structure GS1 and an upper surface of the second gate structure GS2.

The first gate spacer 140 may be formed on the first insulating pattern 104 and the field insulating film 106. The first gate spacer 140 may extend along a side surface of the first gate structure GS1. In some example embodiments, a portion of the first gate dielectric film 132 may be interposed between the first gate electrode 134 and the first gate spacer 140. For example, as illustrated in FIG. 4, the first gate dielectric film 132 may further extend along at least a portion of an inner side surface of the first gate spacer 140. The first gate dielectric film 132 may be formed by a replacement process, but example embodiments are not limited thereto.

The second gate spacer 240 may be formed on the second insulating pattern 204 and the field insulating film 106. The second gate spacer 240 may extend along a side surface of the second gate structure GS2. In some example embodiments, a portion of the second gate dielectric film 232 may be interposed between the second gate electrode 234 and the second gate spacer 240. For example, as illustrated in FIG. 5, the second gate dielectric film 232 may further extend along at least a portion of an inner side surface of the second gate spacer 240. The second gate dielectric film 232 may be formed by a replacement process, but example embodiments are not limited thereto.

Each of the first gate spacer 140 and the second gate spacer 240 may include, for example, at least one of silicon nitride, silicon oxynitride, silicon oxycarbide, silicon boron nitride, silicon carbonitride, silicon oxycarbonitride, or a combination thereof, but example embodiments are not limited thereto. As an example, each of the first gate spacer 140 and the second gate spacer 240 may include a silicon nitride film.

The first source/drain pattern 160 may be formed on at least one side surface (e.g., both side surfaces) of the first gate structure GS1. The first source/drain pattern 160 may be connected to the first active pattern AP1. For example, each of the first bridge patterns 111 to 114 may penetrate through the first gate structure GS1 and the first gate spacer 140 and be connected to the first source/drain pattern 160. The first source/drain pattern 160 may be electrically separated from the first gate electrode 134 by the first gate spacer 140 and/or the first gate dielectric film 132.

In some example embodiments, the first 2D channel layer 124 may further extend along a side surface of the first source/drain pattern 160. For example, a portion of the first 2D channel layer 124 may extend along the side surface of the first source/drain pattern 160 between each of respective adjacent pairs of the first bridge patterns 111 to 114. A portion of the first 2D channel layer 124 may be interposed between the first gate structure GS1 and the first source/drain pattern 160.

In some example embodiments, the first source/drain pattern 160 may include an epitaxial layer. For example, the first source/drain pattern 160 may be formed from the first active pattern AP1 by an epitaxial growth method. The first source/drain pattern 160 may be provided as a source/drain region of a field effect transistor (FET) formed on the first region I.

When the first region I is an NFET region, the first source/drain pattern 160 including the epitaxial layer may include n-type impurities (e.g., phosphorus (P), antimony (Sb), or arsenic (As)) or impurities for blocking or preventing diffusion of n-type impurities. When the first region I is the NFET region, the first source/drain pattern 160 including the epitaxial layer may further include a tensile stress material. As an example, when the first active pattern AP1 is a silicon (Si) pattern, the first source/drain pattern 160 may include a material (e.g., silicon carbide (SiC)) having a smaller lattice constant than silicon (Si).

In some example embodiments, the first source/drain pattern 160 may include metal materials such as nickel (Ni), palladium (Pd), gold (Au), titanium (Ti), silver (Ag), aluminum (Al), tungsten (W), copper (Cu), manganese (Mn), or zirconium (Zr). The first source/drain pattern 160 may be provided as a source/drain electrode connected to the first 2D channel layer 124 including a 2D semiconductor material.

The second source/drain pattern 260 may be formed on at least one side surface (e.g., both side surfaces) of the second gate structure GS2. The second source/drain pattern 260 may be connected to the second active pattern AP2. For example, each of the second bridge patterns 211 to 214 may penetrate through the second gate structure GS2 and the second gate spacer 240 and be connected to the second source/drain pattern 260. The second source/drain pattern 260 may be electrically separated from the second gate electrode 234 by the second gate spacer 240 and/or the second gate dielectric film 232.

In some example embodiments, the second 2D channel layer 224 may further extend along a side surface of the second source/drain pattern 260. For example, a portion of the second 2D channel layer 224 may extend along the side surface of the second source/drain pattern 260 between each of respective adjacent pairs of the second bridge patterns 211 to 214. A portion of the second 2D channel layer 224 may be interposed between the second gate structure GS2 and the second source/drain pattern 260.

In some example embodiments, the second source/drain pattern 260 may include an epitaxial layer. For example, the second source/drain pattern 260 may be formed from the second active pattern AP2 by an epitaxial growth method. The second source/drain pattern 260 may be provided as a source/drain region of a field effect transistor (FET) formed on the second region II.

When the second region II is a PFET region, the second source/drain pattern 260 including the epitaxial layer may include p-type impurities (e.g., boron (B), indium (In), gallium (Ga), or aluminum (Al)) or impurities for blocking or preventing diffusion of p-type impurities. When the second region II is the PFET region, the second source/drain pattern 260 including the epitaxial layer may further include a compressive stress material. As an example, when the second active pattern AP2 is a silicon (Si) pattern, the second source/drain pattern 260 may include a material (e.g., silicon germanium (SiGe)) having a larger lattice constant than silicon (Si).

In some example embodiments, the second source/drain pattern 260 may include metal materials such as nickel (Ni), palladium (Pd), gold (Au), titanium (Ti), silver (Ag), aluminum (Al), tungsten (W), copper (Cu), manganese (Mn), or zirconium (Zr). The second source/drain pattern 260 may be provided as a source/drain electrode connected to the second 2D channel layer 224 including a 2D semiconductor material.

An interlayer insulating film 180 may be formed on the wall structure 102, the first gate structure GS1, the second gate structure GS2, the first source/drain pattern 160, and the second source/drain pattern 260. For example, the interlayer insulating film 180 may cover the wall structure 102, the first gate structure GS1, the second gate structure GS2, the first source/drain pattern 160, and the second source/drain pattern 260.

The interlayer insulating film 180 may include, for example, at least one of silicon oxide, silicon nitride, silicon oxynitride, silicon oxycarbide, silicon boron nitride, silicon boron carbonitride, silicon oxycarbonitride, or a low-k material having a dielectric constant smaller than that of silicon oxide, but example embodiments are not limited thereto. The low-k material may include, for example, at least one of flowable oxide (FOX), torene silazene (TOSZ), undoped silica glass (USG), borosilica glass (BSG), phosphosilica glass (PSG), borophosphosilica glass (BPSG), plasma enhanced tetra ethyl ortho silicate (PETEOS), fluoride silicate glass (FSG), carbon doped silicon oxide (CDO), xerogel, aerogel, amorphous fluorinated carbon, organo silicate glass (OSG), parylene, bis-benzocyclobutenes (BCB), SILK, polyimide, porous polymeric material, or a combination thereof, but example embodiments are not limited thereto.

A first gate contact CB1 may be electrically connected to the first gate structure GS1. For example, the first gate contact CB1 may extend in the third direction Z to penetrate through the interlayer insulating film 180 and be connected to the upper surface of the first gate electrode 134.

A second gate contact CB2 may be electrically connected to the second gate structure GS2. For example, the second gate contact CB2 may extend in the third direction Z to penetrate through the interlayer insulating film 180 and be connected to the upper surface of the second gate electrode 234.

Each of the first gate contact CB1 and the second gate contact CB2 may include, for example, a metal material such as cobalt (Co), titanium (Ti), tantalum (Ta), ruthenium (Ru), tungsten (W), or cobalt tungsten phosphorus (CoWP), but example embodiments are not limited thereto. As an example, each of the first gate contact CB1 and the second gate contact CB2 may include cobalt (Co).

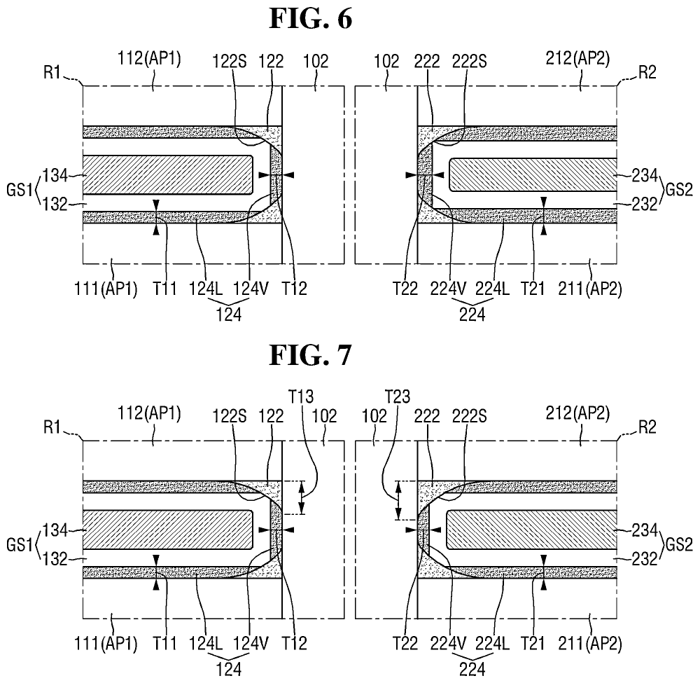

FIGS. 6 to 10 are various enlarged views for describing regions R1 and R2 of FIG. 2, according to some example embodiments. For convenience of explanation, portions overlapping those described above with reference to FIGS. 1 to 5 will be briefly described or omitted.

Referring to FIG. 6, in the semiconductor device according to an example embodiment, the thicknesses T11 and T12 of the first 2D channel layer 124 and the thicknesses T21 and T22 of the second 2D channel layer 224 may be different from each other.

This may be due to the fact that the first 2D channel layer 124 and the second 2D channel layer 224 are formed at different levels. For example, the thickness T11 of the first horizontal portion 124L and the thickness T21 of the second horizontal portion 224L may be different from each other, and/or the thickness T12 of the first vertical portion 124V and the thickness T22 of the second vertical portion 224V may be different from each other.

It is only illustrated that the thicknesses T21 and T22 of the second 2D channel layer 224 are greater than the thicknesses T11 and T12 of the first 2D channel layer 124, respectively, but this is only an example, and the thicknesses T21 and T22 of the second 2D channel layer 224 may be smaller than the thicknesses T1l and T12 of the first 2D channel layer 124, respectively. Depending on purposes or needs, a difference between the thicknesses T11 and T12 of the first 2D channel layer 124 and the thicknesses T21 and T22 of the second 2D channel layer 224 may be appropriately adjusted.

Referring to FIG. 7, in the semiconductor device according to an example embodiment, a thickness T13 of the first seed layer 122 and a thickness T23 of the second seed layer 222 may be different from each other.

This may be due to the fact that the first seed layer 122 and the second seed layer 222 are formed at different levels. The thickness T13 of the first seed layer 122 and the thickness T23 of the second seed layer 222 may each be defined as, for example, a thickness in the vertical direction (e.g., the third direction Z), but this is only an example. As another example, the thickness T13 of the first seed layer 122 and the thickness T23 of the second seed layer 222 may each be defined as a thickness in the horizontal direction (e.g., the second direction Y). As still another example, the thickness T13 of the first seed layer 122 may be defined as a maximum distance from a contact point between the first active pattern AP1 and the wall structure 102 to the first surface 122S, and the thickness T23 of the second seed layer 222 may be defined as a maximum distance from a contact point between the second active pattern AP2 and the wall structure 102 to the second surface 222S.

It is only illustrated that the thickness T23 of the second seed layer 222 is greater than the thickness T13 of the first seed layer 122, but this is only an example, and the thickness T23 of the second seed layer 222 may be smaller than the thickness T13 of the first seed layer 122. Depending on purposes or needs, a difference between the thickness T13 of the first seed layer 122 and the thickness T23 of the second seed layer 222 may be appropriately adjusted.

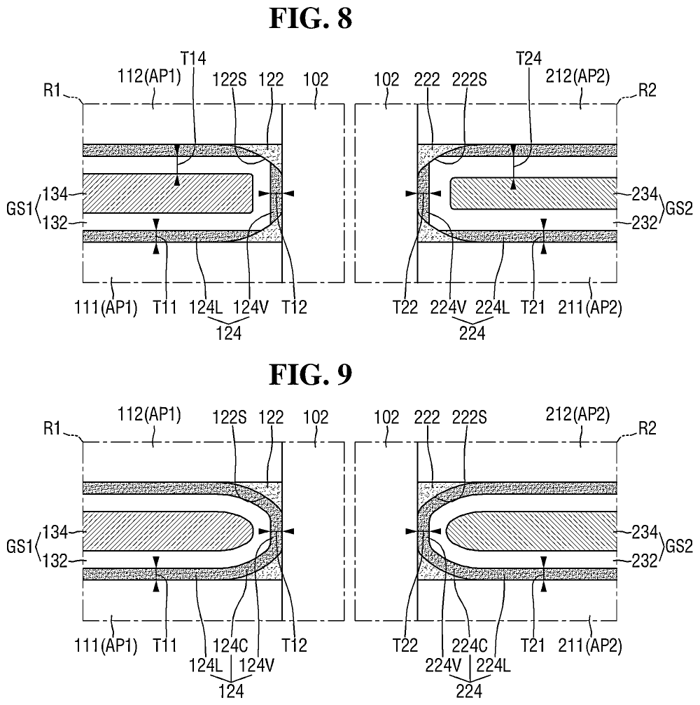

Referring to FIG. 8, in the semiconductor device according to an example embodiment, a thickness T14 of the first gate dielectric film 132 and a thickness T24 of the second gate dielectric film 232 may be different from each other.

This may be due to the fact that the first gate dielectric film 132 and the second gate dielectric film 232 are formed at different levels. It is only illustrated that the thickness T24 of the second gate dielectric film 232 is greater than the thickness T14 of the first gate dielectric film 132, but this is only an example, and the thickness T24 of the second gate dielectric film 232 may be smaller than the thickness T14 of the first gate dielectric film 132. Depending on purposes or needs, a difference between the thickness T14 of the first gate dielectric film 132 and the thickness T24 of the second gate dielectric film 232 may be appropriately adjusted.

Referring to FIG. 9, in the semiconductor device according to an example embodiment, the first 2D channel layer 124 may extend along the first surface 122S, or the second 2D channel layer 224 may extend along the second surface 222S.

For example, the first 2D channel layer 124 may further include a first connection portion 124C extending along the first surface 122S and connecting the first horizontal portion 124L and the first vertical portion 124V. Likewise, the second 2D channel layer 224 may further include a second connection portion 224C extending along the second surface 222S and connecting the second horizontal portion 224L and the second vertical portion 224V.

It is only illustrated in FIG. 9 that the first connection portion 124C completely covers the first surface 122S and the second connection portion 224C completely covers the second surface 222S, but this is only an example. As an example, the first 2D channel layer 124 may expose a portion of the first surface 122S, or the second 2D channel layer 224 may expose a portion of the second surface 222S.

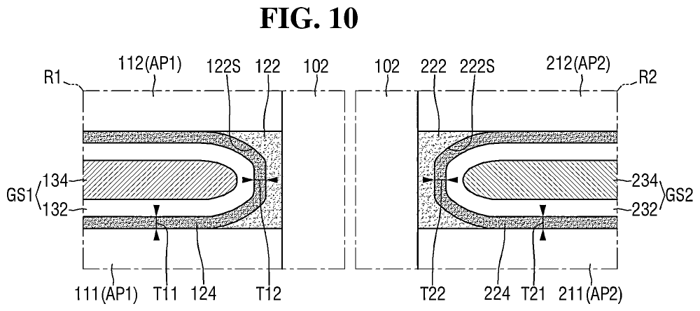

Referring to FIG. 10, in the semiconductor device according to an example embodiment, the first 2D channel layer 124 may be spaced apart from the wall structure 102, or the second 2D channel layer 224 may be spaced apart from the wall structure 102.

For example, the first seed layer 122 may completely cover the side surface of the wall structure 102 between each of respective adjacent pairs of the first bridge patterns 111 to 114. Likewise, the second seed layer 222 may completely cover the side surface of the wall structure 102 between the second bridge patterns 211 to 214.

It is only illustrated in FIG. 10 that the first seed layer 122 completely covers the side surface of the wall structure 102 between the first bridge patterns 111 and 112 from among the first bridge patterns 111 to 114, and the second seed layer 222 completely covers the side surface of the wall structure 102 between the second bridge patterns 211 and 212 from among the second bridge patterns 211 to 214, but this is only an example. As another example, the first seed layer 122 may expose a portion of the side surface of the wall structure 102 between the first bridge patterns 111 to 114, or the second seed layer 222 may expose the side surface of the wall structure 102 between the second bridge patterns 211 to 214.

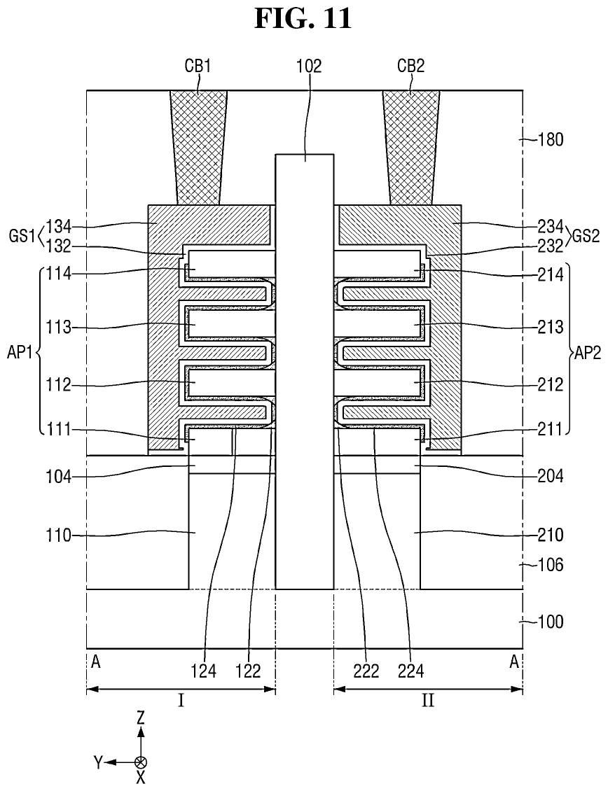

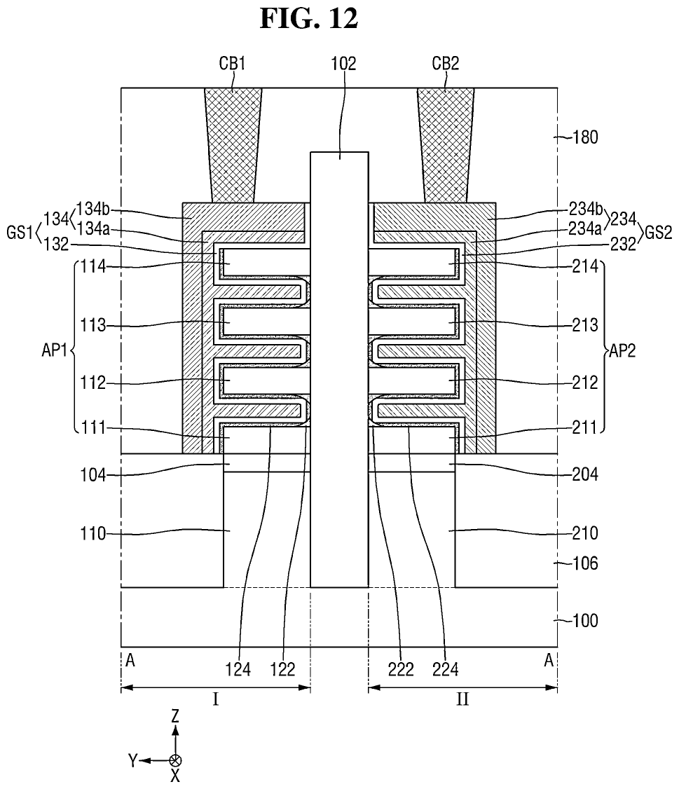

FIGS. 11 and 12 are other various cross-sectional views for describing a semiconductor device according to some example embodiments. For convenience of explanation, portions overlapping those described above with reference to FIGS. 1 to 10 will be briefly described or omitted.

Referring to FIG. 11, in the semiconductor device according to an example embodiment, an uppermost portion of the first 2D channel layer 124 may be lower than an upper surface of the uppermost bridge pattern (e.g., the fourth sheet pattern 114) and an uppermost portion of the second 2D channel layer 224 may be lower than an upper surface of the uppermost bridge pattern (e.g., the eighth sheet pattern 118).

For example, the first 2D channel layer 124 may extend along a lower surface of the fourth sheet pattern 114 from the first seed layer 122 adjacent to the lower surface of the fourth sheet pattern 114 and then extend only along a portion of a side surface of the fourth sheet pattern 114. The second 2D channel layer 224 may extend along a lower surface of the eighth sheet pattern 214 from the second seed layer 222 adjacent to the lower surface of the eighth sheet pattern 214 and then extend only along a portion of a side surface of the eighth sheet pattern 214.

In this example embodiment, a lowermost portion of the first 2D channel layer 124 may be higher than a lower surface of a lowermost bridge pattern (e.g., the first sheet pattern 111) and a lowermost portion of the second 2D channel layer 224 may be higher than a lower surface of a lowermost bridge pattern (e.g., the fifth sheet pattern 211).

For example, the first 2D channel layer 124 may extend along an upper surface of the first sheet pattern 111 from the first seed layer 122 adjacent to the upper surface of the first sheet pattern 111 and then extend only along a portion of a side surface of the first sheet pattern 111. The second 2D channel layer 224 may extend along an upper surface of the fifth sheet pattern 211 from the second seed layer 222 adjacent to the upper surface of the fifth sheet pattern 211 and then extend only along a portion of a side surface of the fifth sheet pattern 211.

Referring to FIG. 12, in the semiconductor device according to an example embodiment, the first gate electrode 134 may be formed by stacking a plurality of conductive films and the second gate electrode 234 may be formed by stacking a plurality of conductive films.

For example, the first gate electrode 134 may include a first work function adjusting film 134a for adjusting a work function and a first filling conductive film 134b for filling a space formed by the first work function adjusting film 134a. The second gate electrode 234 may include a second work function adjusting film 234a for adjusting a work function and a second filling conductive film 234b for filling a space formed by the second work function adjusting film 234a.

It is only illustrated that the first work function adjusting film 134a and the second work function adjusting film 234a have the same thickness, but this is only an example, and the first work function adjusting film 134a and the second work function adjusting film 234a may also have different thicknesses.

Each of the first work function adjusting film 134a and the second work function adjusting film 234a may include, for example, at least one of TiN, TaN, TiC, TaC, TiAlC, or a combination thereof. The first filling conductive film 134b and the second filling conductive film 234b may each include, for example, W or Al.

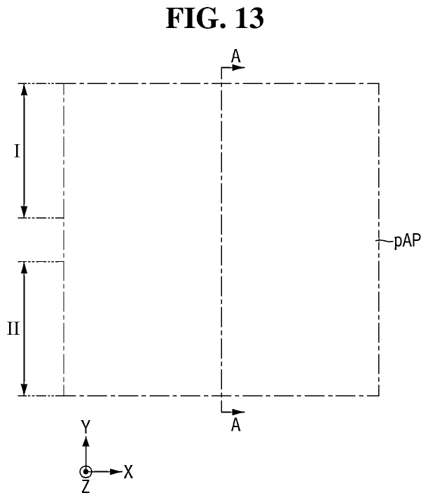

FIGS. 13 to 43 are intermediate step views for describing a method for fabricating a semiconductor device according to an example embodiment. For convenience of explanation, portions overlapping those described above with reference to FIGS. 1 to 12 will be briefly described or omitted.

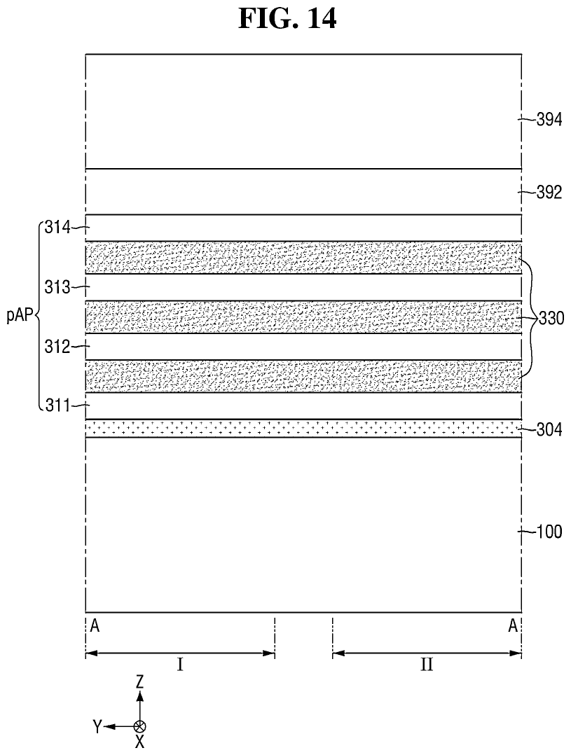

Referring to FIGS. 13 and 14, a first sacrificial film 304, an active film pAP, a second sacrificial film 330, and at least one passivation film 392 or 394 are formed on the substrate 100. For reference, FIG. 14 is a cross-sectional view taken along line A-A of FIG. 13.

The first sacrificial film 304 may be formed on the substrate 100. The first sacrificial film 304 may have an etch selectivity with respect to the substrate 100 and the active film pAP. As an example, the substrate 100 and the active film pAP may include silicon (Si), and the first sacrificial film 304 may include silicon germanium (SiGe).

The active film pAP and the second sacrificial film 330 may be formed on the first sacrificial film 304. The active film pAP and the second sacrificial film 330 may be alternately stacked on the first sacrificial film 304. For example, the active film pAP may include a plurality of sub-active films 311 to 314 sequentially stacked on the first sacrificial film 304. The second sacrificial film 330 may be interposed between each of respective adjacent pairs of the sub-active films 311 to 314 to space the sub-active films 311 to 314 apart from each other in the vertical direction (e.g., in the third direction Z).

The second sacrificial film 330 may include a transition metal element. The transition metal element may include, for example, at least one metal element of molybdenum (Mo), tungsten (W), niobium (Nb) vanadium (V), tantalum (Ta), titanium (Ti), zirconium (Zr), hafnium (Hf), technetium (Tc), rhenium (Re), or copper (Cu). As an example, the second sacrificial film 330 may include molybdenum (Mo) or tungsten (W).

In some example embodiments, the second sacrificial film 330 may include an oxide of the transition metal element. As an example, the second sacrificial film 330 may include molybdenum dioxide (MoO₂) or tungsten dioxide (WO₂).

At least one passivation film 392 or 394 may be formed on the active film pAP and the second sacrificial film 330. At least one of the passivation film 392 or 394 may include various materials that protect the active film pAP and/or the second sacrificial film 330 in a subsequent process. As an example, a first passivation film 392 including silicon oxide (SiO) and a second passivation film 394 including amorphous silicon (a-Si) may be sequentially stacked on the active film pAP and the second sacrificial film 330.

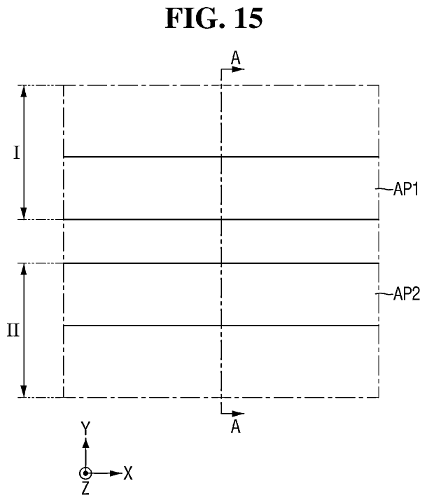

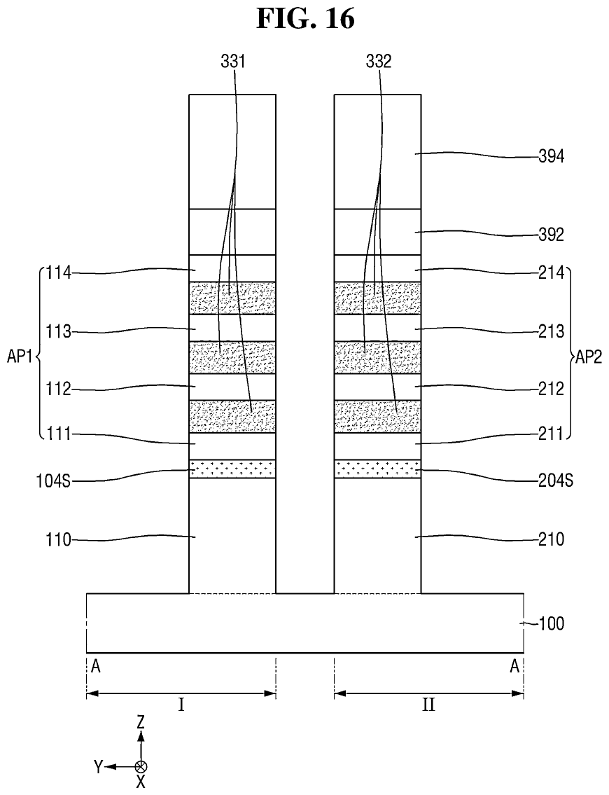

Referring to FIGS. 15 and 16, a first sacrificial pattern 104S, a second sacrificial pattern 204S, a first active pattern AP1, a third sacrificial pattern 331, a second active pattern AP2, and a fourth sacrificial pattern 332 are formed on the substrate 100. For reference, FIG. 16 is a cross-sectional view taken along line A-A of FIG. 15.

The first sacrificial pattern 104S, the second sacrificial pattern 204S, the first active pattern AP1, the third sacrificial pattern 331, the second active pattern AP2, and the fourth sacrificial pattern 332 may each extend in the first direction X. For example, a patterning process of patterning the first sacrificial film 304, the active film pAP, the second sacrificial film 330, and at least one passivation film 392 or 394 of FIGS. 13 and 14 may be performed. The first sacrificial film 304 patterned in the first region I may form the first sacrificial pattern 104S, and the first sacrificial film 304 patterned in the second region II may form the second sacrificial pattern 204S. The active film pAP patterned in the first region I may form the first active pattern AP1, and the second sacrificial film 330 patterned in the first region I may form the third sacrificial pattern 331 alternately stacked with the first active pattern AP1. In addition, the active film pAP patterned in the second region II may form the second active pattern AP2, and the second sacrificial film 330 patterned in the second region II may form the fourth sacrificial pattern 332 alternately stacked with the second active pattern AP2.

In some example embodiments, in a process of etching the first sacrificial film 304, a portion of the substrate 100 may be etched to form a first fin pattern 110 on the first region I and a second fin pattern 210 on the second region II.

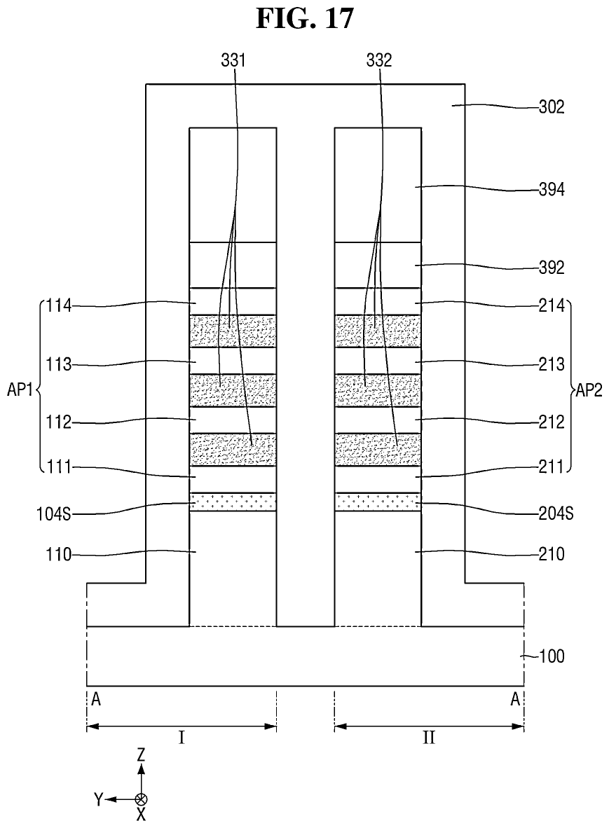

Referring to FIG. 17, a filling insulating film 302 serving as a filling function is formed. The filling insulating film 302 may fill at least a region between the first active pattern AP1 and the second active pattern AP2. For example, the filling insulating film 302 may cover the resultant structure of FIG. 16. The filling insulating film 302 may include, for example, at least one of silicon oxide, silicon nitride, silicon oxynitride, or a combination thereof, but example embodiments are not limited thereto. As an example, the filling insulating film 302 may include a silicon nitride film.

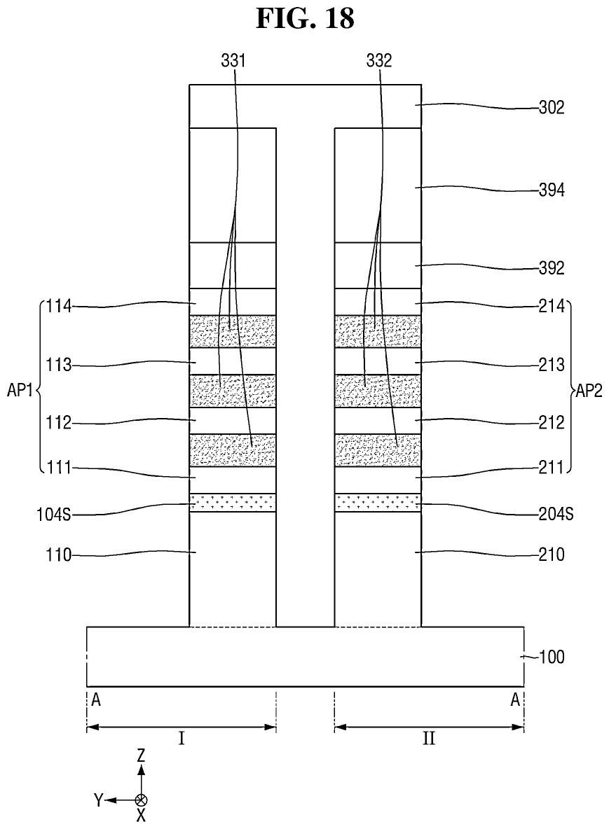

Referring to FIG. 18, the first sacrificial pattern 104S and the second sacrificial pattern 204S are exposed.

For example, a portion of the filling insulating film 302 may be removed to expose side surfaces of the first sacrificial pattern 104S and the second sacrificial pattern 204S. In some example embodiments, the filling insulating film 302 filling the region between the first active pattern AP1 and the second active pattern AP2 may not be removed.

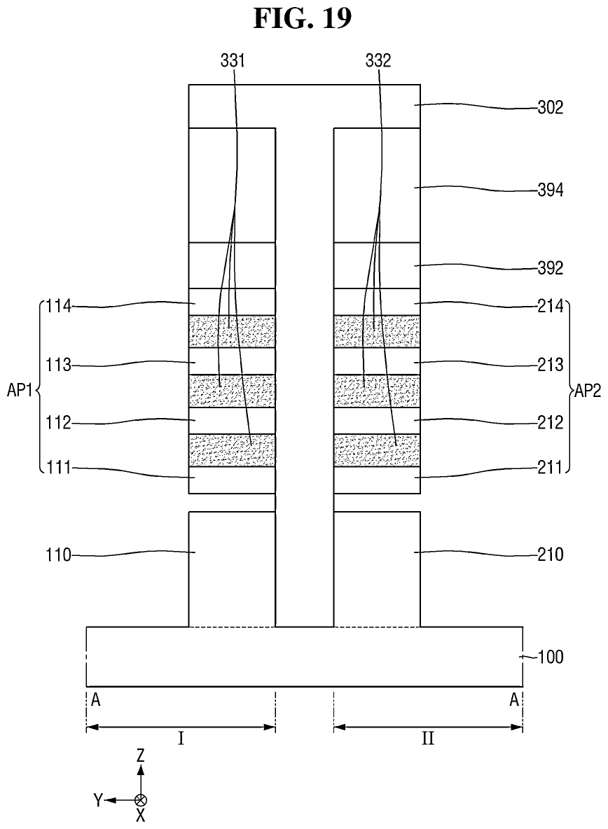

Referring to FIG. 19, the first sacrificial pattern 104S and the second sacrificial pattern 204S are removed.

Because the first sacrificial pattern 104S and the second sacrificial pattern 204S may have an etch selectivity with respect to the substrate 100 and the active film pAP, the first sacrificial pattern 104S and the second sacrificial pattern 204S may be selectively removed. The third sacrificial pattern 331 and the fourth sacrificial pattern 332 may not be removed.

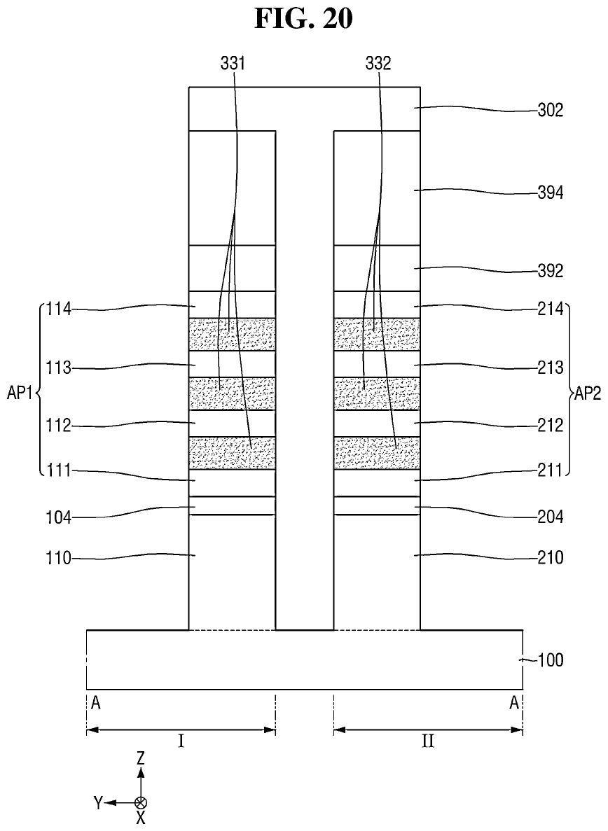

Referring to FIG. 20, a first insulating pattern 104 and a second insulating pattern 204 are formed.

The first insulating pattern 104 may fill a region from which the first sacrificial pattern 104S is removed, and the second insulating pattern 204 may fill a region from which the second sacrificial pattern 204S is removed. Each of the first insulating pattern 104 and the second insulating pattern 204 may include, for example, at least one of silicon oxide, silicon nitride, silicon oxynitride, or a combination thereof, but example embodiments are not limited thereto. For example, each of the first insulating pattern 104 and the second insulating pattern 204 may include a silicon nitride film.

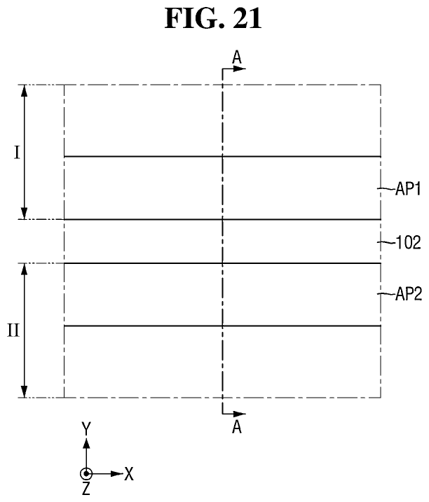

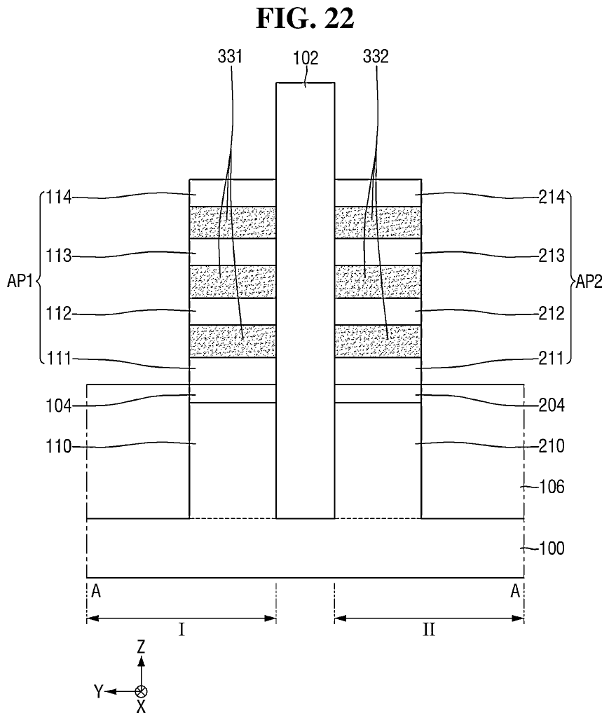

Referring to FIGS. 21 and 22, a wall structure 102 is formed. For reference, FIG. 22 is a cross-sectional view taken along line A-A of FIG. 21.

For example, the filling insulating film 302 on at least one passivation film 392 or 394 may be removed. Subsequently, at least one passivation film 392 or 394 may be removed. Through this, the wall structure 102 separating the first active pattern AP1 and the second active pattern AP2 may be formed from at least a portion of the filling insulating film 302 filling the region between the first active pattern AP1 and the second active pattern AP2.

In some example embodiments, a field insulating film 106 may be formed on the substrate 100. The field insulating film 106 may cover at least a portion of a side surface of the first fin pattern 110 and at least a portion of a side surface of the second fin pattern 210. The field insulating film 106 may include, for example, at least one of silicon oxide, silicon nitride, silicon oxynitride, or a combination thereof, but example embodiments are not limited thereto. As an example, the field insulating film 106 may include a silicon oxide film.

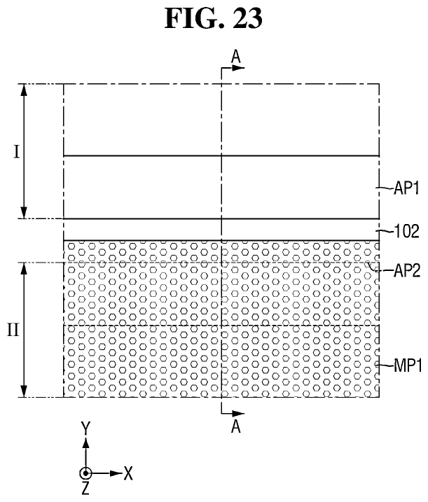

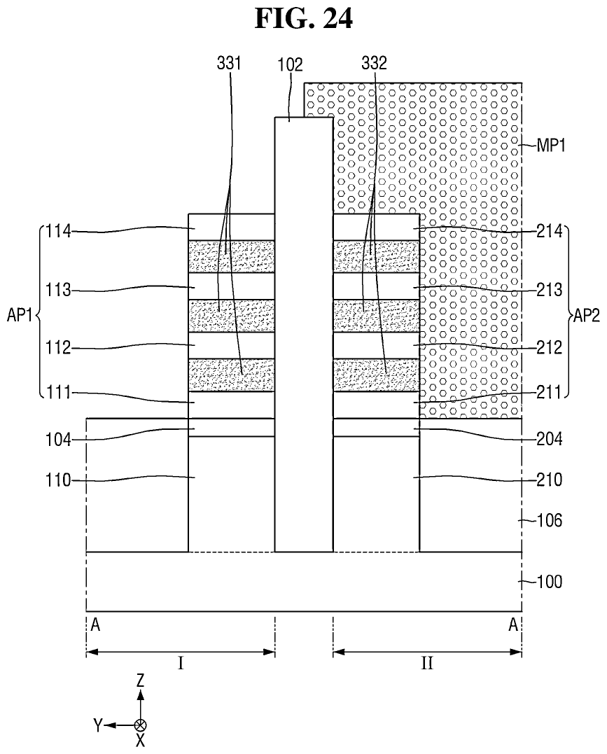

Referring to FIGS. 23 and 24, a first mask pattern MP1 is formed on the second region II of the substrate 100. For reference, FIG. 24 is a cross-sectional view taken along line A-A of FIG. 23.

The first mask pattern MP1 may cover the second region II of the substrate 100. For example, the first mask pattern MP1 may cover the second active pattern AP2 and the fourth sacrificial pattern 332. The first mask pattern MP1 may cover at least a portion of the wall structure 102, but example embodiments are not limited thereto.

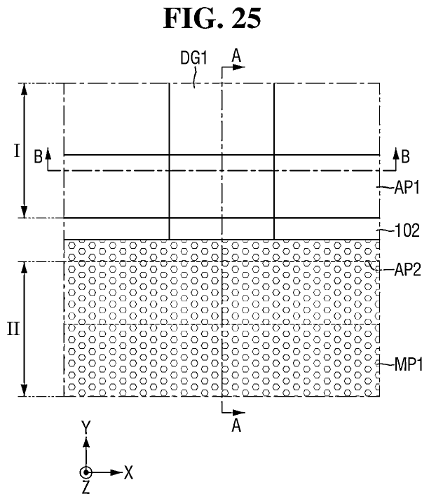

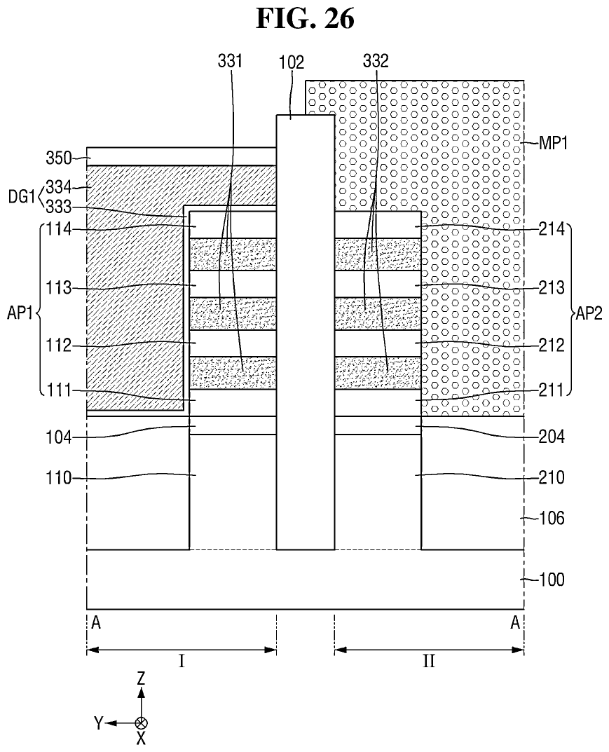

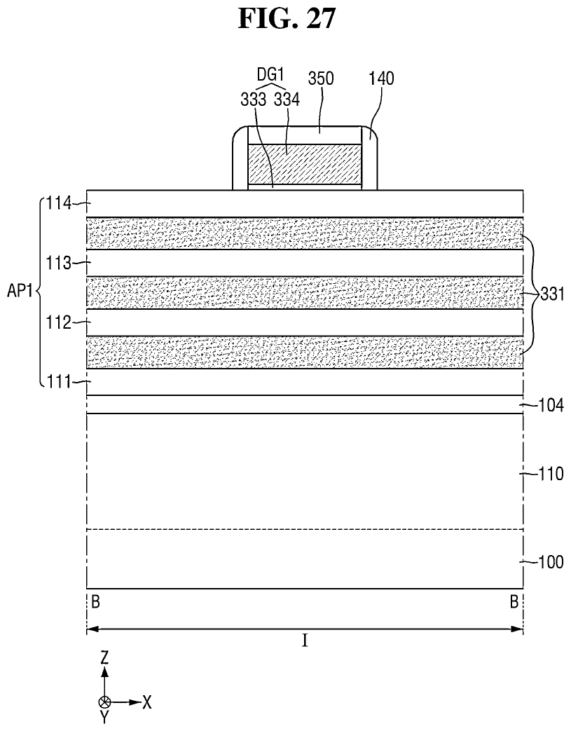

Referring to FIGS. 25 to 27, a first dummy gate structure DG1 and a first gate spacer 140 are formed on the first region I of the substrate 100. For reference, FIG. 26 is a cross-sectional view taken along line A-A of FIG. 25, and FIG. 27 is a cross-sectional view taken along line B-B of FIG. 25.

The first dummy gate structure DG1 may intersect the first active pattern AP1 and the third sacrificial pattern 331. For example, the first dummy gate structure DG1 may extend in the second direction Y on a side surface of the wall structure 102.

The first dummy gate structure DG1 may include a first dummy gate dielectric film 333 and a first dummy gate electrode 334. For example, a dielectric film and an electrode film sequentially stacked on the first region I of the substrate 100 may be formed. Subsequently, a first gate mask 350 extending in a second direction Y may be formed on the electrode film on the first region I. Subsequently, a patterning process of patterning the dielectric film and the electrode film by using the first gate mask 350 as an etching mask may be performed. The patterned dielectric film may form the first dummy gate dielectric film 333, and the patterned electrode film may form the first dummy gate electrode 334.

The first dummy gate structure DG1 may have an etch selectivity with respect to the first active pattern AP1. As an example, the first dummy gate electrode 334 may include poly-Si.

Subsequently, a first gate spacer 140 may be formed on a side surface of the first dummy gate structure DG1. The first gate spacer 140 may extend along the side surface of the first dummy gate structure DG1. The first gate spacer 140 may include, for example, at least one of silicon nitride, silicon oxynitride, silicon oxycarbide, silicon boron nitride, silicon carbonitride, silicon oxycarbonitride, or a combination thereof, but example embodiments are not limited thereto.

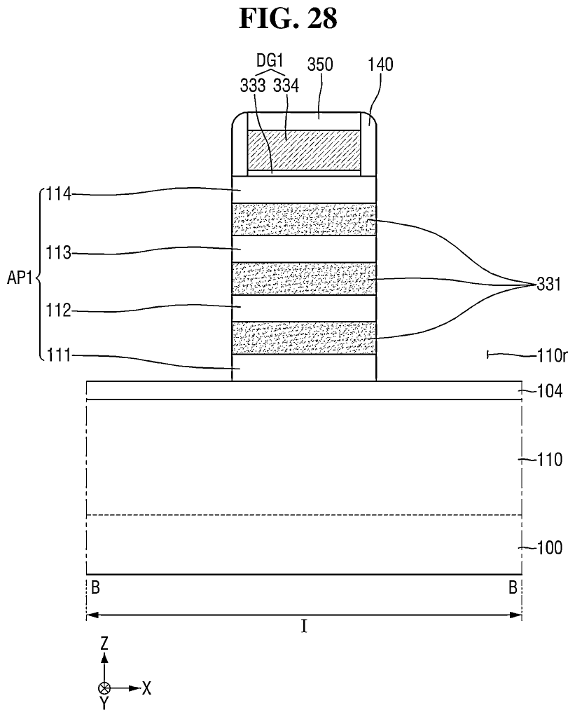

Referring to FIG. 28, an etching process is performed on the first active pattern AP1 and the third sacrificial pattern 331.

In the etching process, for example, the first dummy gate structure DG1 and the first gate spacer 140 may be used as an etching mask. As the etching process is performed, a portion of the first active pattern AP1 and a portion of the third sacrificial pattern 331 disposed outside the first dummy gate structure DG1 may be removed to form a first recess 110r. In some example embodiments, the first recess 110r may be defined on an upper surface of the first insulating pattern 104.

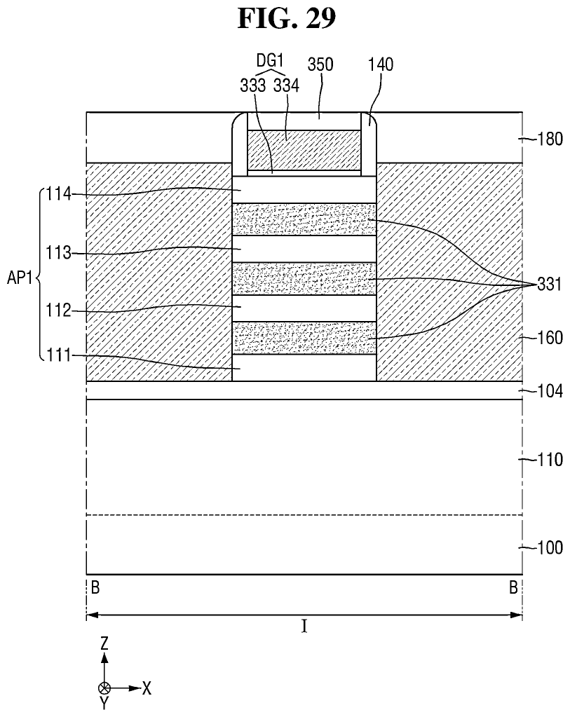

Referring to FIG. 29, a first source/drain pattern 160 and an interlayer insulating film 180 are formed.

The first source/drain pattern 160 may fill at least a portion of the first recess 110r of FIG. 28. Through this, the first source/drain pattern 160 connected to the first active pattern AP1 may be formed.

In some example embodiments, the first source/drain pattern 160 may include an epitaxial layer. For example, the first source/drain pattern 160 may be formed from the first active pattern AP1 by an epitaxial growth method.

In some example embodiments, the first source/drain pattern 160 may include metal materials such as nickel (Ni), palladium (Pd), gold (Au), titanium (Ti), silver (Ag), aluminum (Al), tungsten (W), copper (Cu), manganese (Mn), or zirconium (Zr). For example, the first source/drain pattern 160 may be formed by a deposition method.

Subsequently, an interlayer insulating film 180 covering the first source/drain pattern 160 may be formed. The interlayer insulating film 180 may include, for example, at least one of silicon oxide, silicon nitride, silicon oxynitride, silicon oxycarbide, silicon boron nitride, silicon boron carbonitride, silicon oxycarbonitride, or a low-k material having a dielectric constant smaller than that of silicon oxide, but example embodiments are not limited thereto.

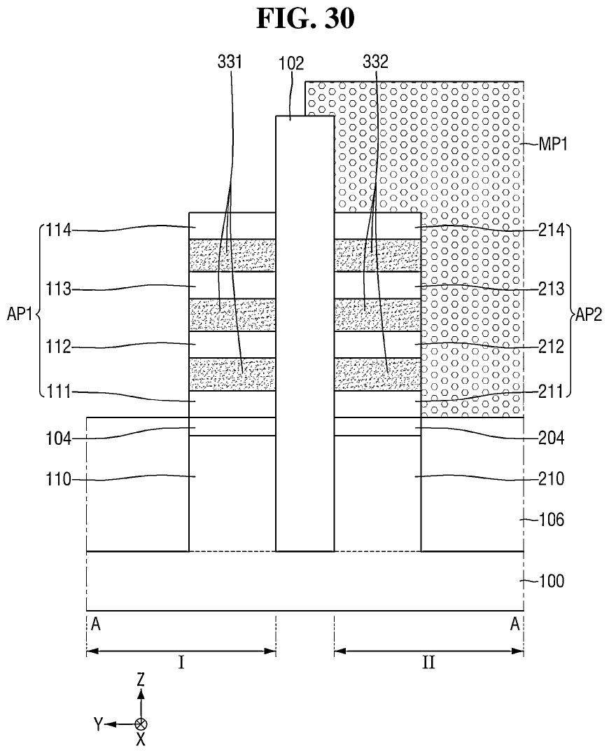

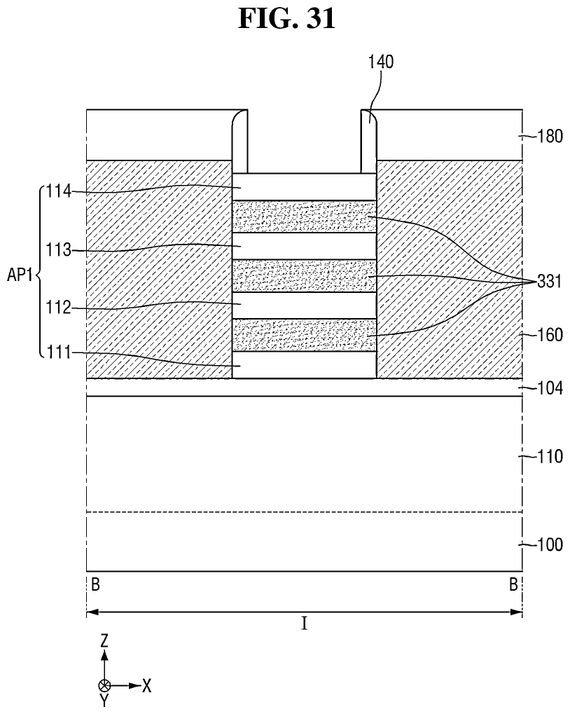

Referring to FIGS. 30 and 31, the first dummy gate structure DG1 is removed.

Because the first dummy gate structure DG1 may have an etch selectivity with respect to the first active pattern AP1, the first dummy gate structure DG1 may be selectively removed. As the first dummy gate structure DG1 is removed, the first active pattern AP1 and the third sacrificial pattern 331 disposed inside the first gate spacer 140 may be exposed.

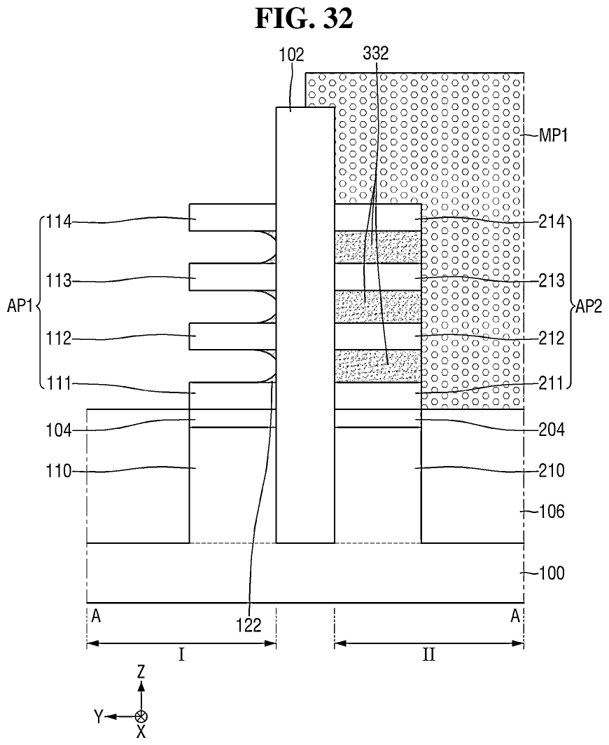

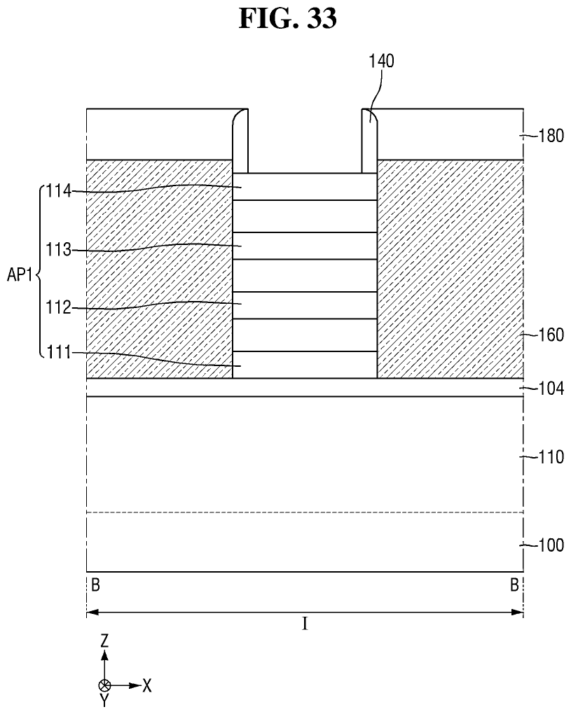

Referring to FIGS. 32 and 33, a first seed layer 122 is formed.

For example, an etching process may be performed on the third sacrificial pattern 331. In the etching process, the third sacrificial pattern 331 may be selectively removed with respect to the first active pattern AP1. Through this, a plurality of first bridge patterns 111 to 114 spaced apart from each other and extending in the first direction X may be formed on the first region I of the substrate 100.

In addition, in the etching process, a portion of the third sacrificial pattern 331 interposed between the first bridge patterns 111 to 114 may not be completely removed due to a narrow space. Through this, the first seed layer 122 remaining on the side surface of the wall structure 102 between each of respective adjacent pairs of the first bridge patterns 111 to 114 may be formed from a portion of the third sacrificial pattern 331.

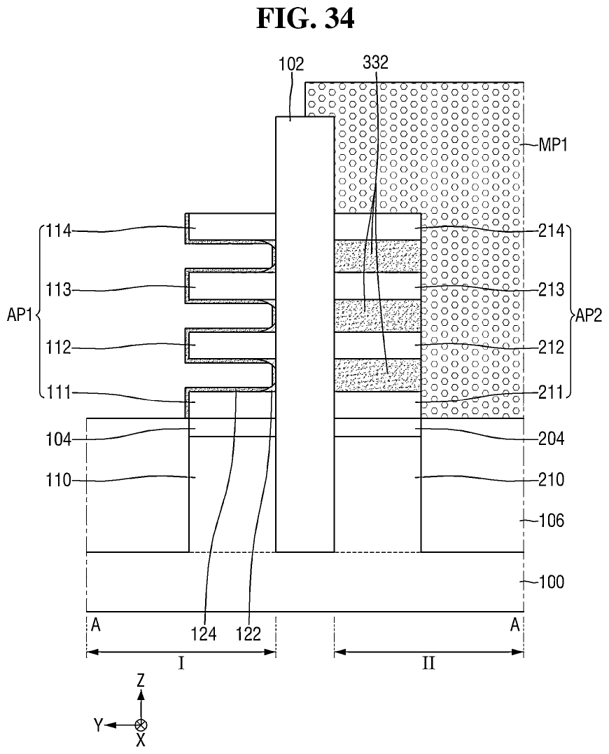

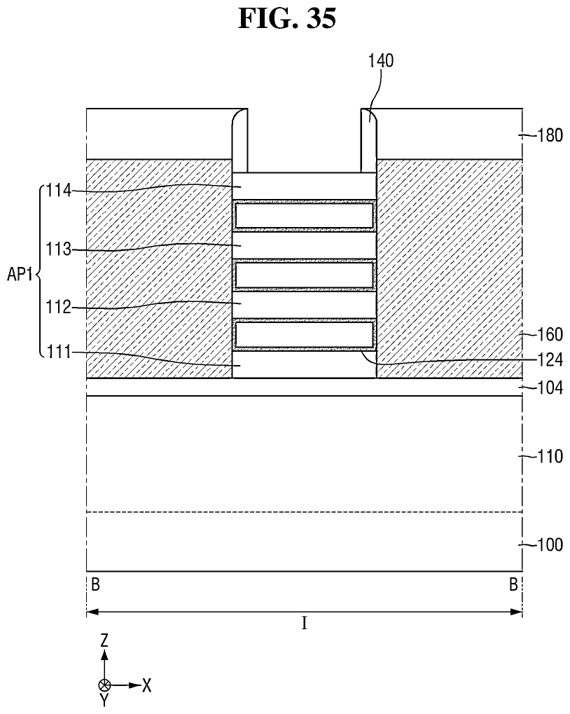

Referring to FIGS. 34 and 35, a first 2D channel layer 124 is formed.

The first 2D channel layer 124 may include a first transition metal dichalcogenide including the transition metal element of the first seed layer 122. The first 2D channel layer 124 may be formed by a crystal growth method using the first seed layer 122 as a seed layer. For example, the first 2D channel layer 124 may be formed by two-dimensionally growing crystals from a surface of the first seed layer 122 exposed from the first active pattern AP1 and the wall structure 102.

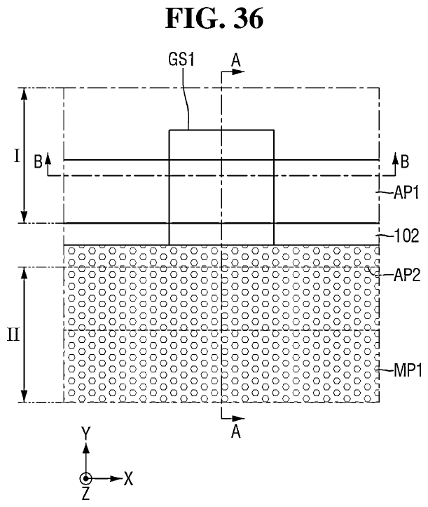

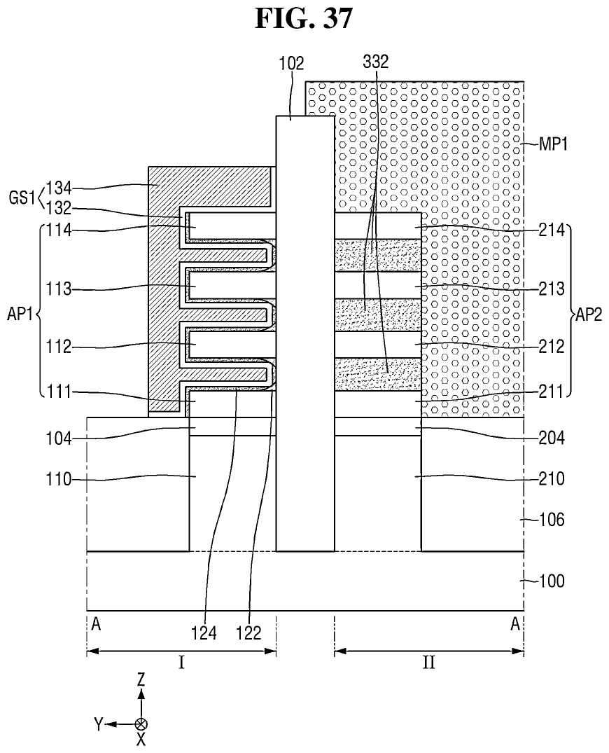

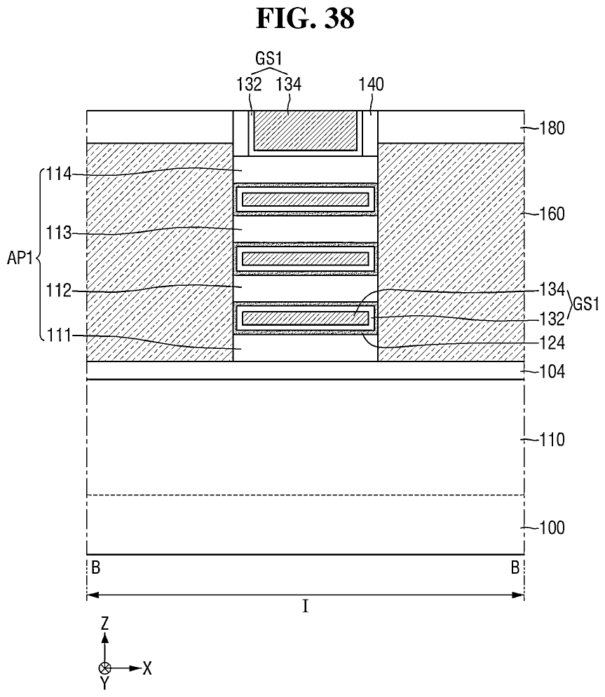

Referring to FIGS. 36 to 38, a first gate structure GS1 is formed. For reference, FIG. 37 is a cross-sectional view taken along line A-A of FIG. 36, and FIG. 38 is a cross-sectional view taken along line B-B of FIG. 36.

For example, the first gate dielectric film 132 and the first gate electrode 134 may be sequentially stacked on the first active pattern AP1. Subsequently, a patterning process may be performed on the first gate dielectric film 132 and the first gate electrode 134. Through this, the first gate structure GS1 surrounding a circumference of each of the first bridge patterns 111 to 114 may be formed.

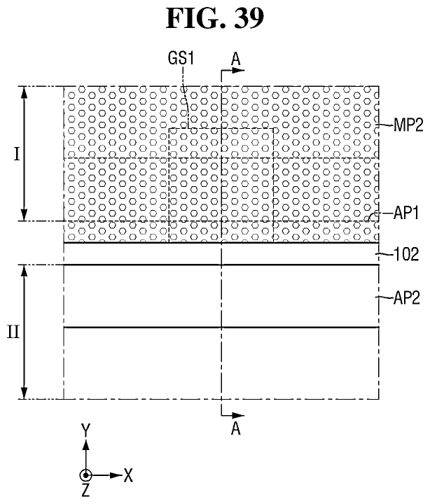

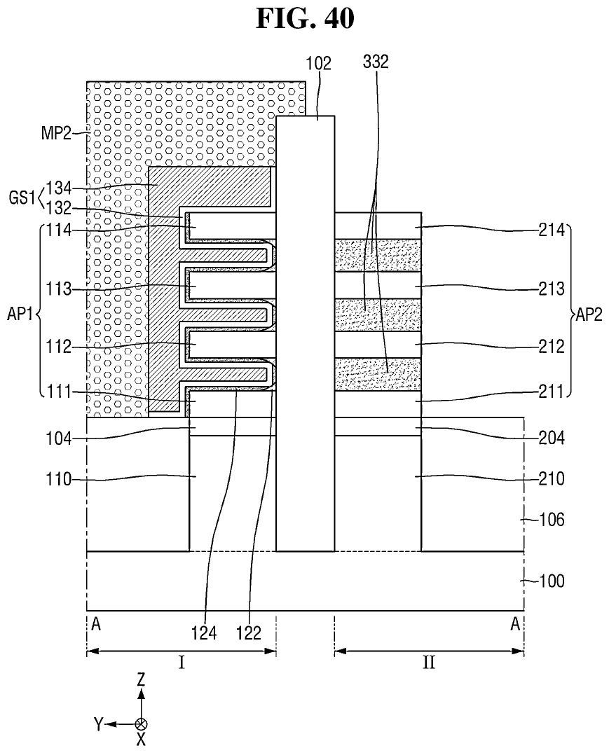

Referring to FIGS. 39 and 40, a second mask pattern MP2 is formed on the first region I of the substrate 100. For reference, FIG. 40 is a cross-sectional view taken along line A-A of FIG. 39.

The second mask pattern MP2 may cover the first region I of the substrate 100. For example, the second mask pattern MP2 may cover the first active pattern AP1, the first source/drain pattern 160, and the first gate structure GS1. The second mask pattern MP2 may cover at least a portion of the wall structure 102, but example embodiments are not limited thereto.

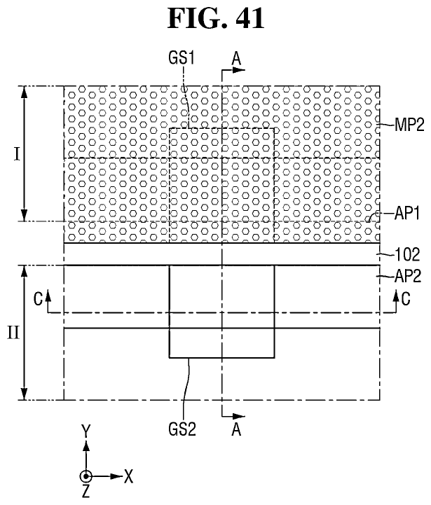

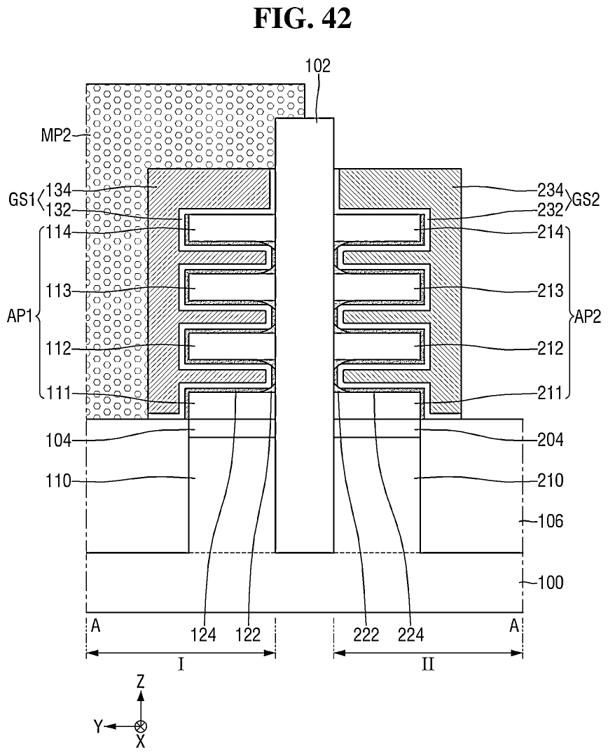

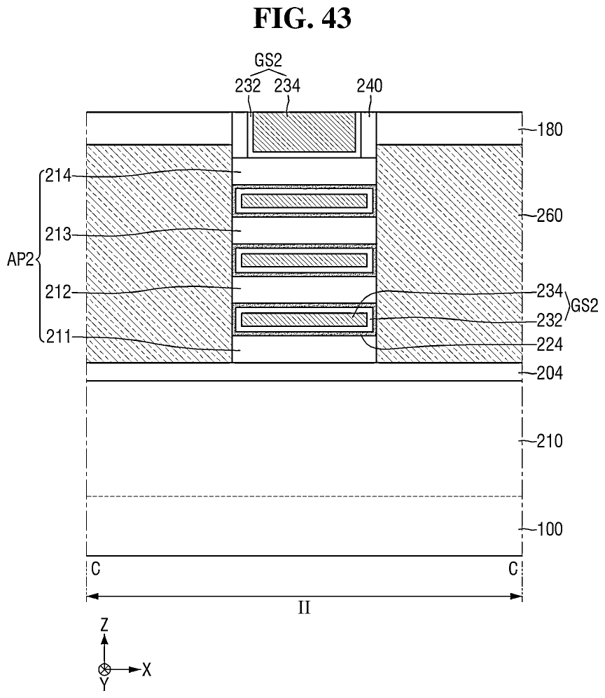

Referring to FIGS. 41 to 43, a second source/drain pattern 260, a second seed layer 222, a second 2D channel layer 224, and a second gate structure GS2 are formed on the second region II of the substrate 100. For reference, FIG. 42 is a cross-sectional view taken along line A-A of FIG. 41, and FIG. 43 is a cross-sectional view taken along line B-B of FIG. 41. Except for being formed on the second region II of the substrate 100, forming the second source/drain pattern 260, the second seed layer 222, the second 2D channel layer 224, and the second gate structure GS2 may be similar to forming the first source/drain pattern 160, the first seed layer 122, the first 2D channel layer 124, and the first gate structure GS1, and thus a detailed description thereof will be omitted.

Subsequently, referring to FIGS. 1 to 5, a first gate contact CB1 connected to the first gate structure GS1 and a second gate contact CB2 connected to the second gate structure GS2 are formed. Through this, the semiconductor device described above with reference to FIGS. 1 to 5 may be fabricated.

Meanwhile, as a method for improving performance of a semiconductor device by improving mobility and short channel effect (SCE), a semiconductor device using a two-dimensional semiconductor material as a channel is being studied. However, the two-dimensional semiconductor material has problems such as poor compatibility with commercially available structures and processes based on silicon (Si) due to material characteristics thereof, and difficulty in forming due to a very thin thickness thereof.

In the semiconductor device and the method for fabricating the same according to some example embodiments, the transition metal material (e.g., the first seed layer 122 and/or the second seed layer 222) remaining between the bridge patterns may be used as the seed layer for forming the transition metal chalcogenide material (e.g., the first 2D channel layer 124 and/or the second 2D channel layer 224). Through this, the first 2D channel layer 124 and/or the second 2D channel layer 224 including the transition metal chalcogenide material may be formed. In addition, the first 2D channel layer 124 and/or the second 2D channel layer 224 may have a single crystal structure and may have high compatibility with commercially available structures and processes based on silicon (Si). Through this, a semiconductor device having improved performance may be provided by using the 2D semiconductor material as a channel region through a simple method.

While the present inventive concepts have been particularly shown and described with reference to some example embodiments thereof, it will be understood by those of ordinary skill in the art that various changes in form and details may be made therein without departing from the spirit and scope of the present inventive concepts as defined by the following claims. It is therefore desired that the present embodiments be considered in all respects as illustrative and not restrictive, reference being made to the appended claims rather than the foregoing description to indicate the scope of the inventive concepts.

1. A semiconductor device comprising:
a substrate including a first region and a second region;
a first active pattern extending in a first direction on the first region;
a second active pattern extending in the first direction on the second region;
a wall structure extending in the first direction between the first region and the second region and separating the first active pattern and the second active pattern from each other;
a first gate structure intersecting the first active pattern on the first region;
a first two-dimensional (2D) channel layer including a first transition metal dichalcogenide between the first active pattern and the first gate structure;
a second gate structure intersecting the second active pattern on the second region; and
a second 2D channel layer including a second transition metal dichalcogenide between the second active pattern and the second gate structure.

2. The semiconductor device of claim 1, wherein the first transition metal dichalcogenide and the second transition metal dichalcogenide include a same transition metal element.

3. The semiconductor device of claim 1, wherein the first active pattern includes a plurality of bridge patterns sequentially stacked on the first region, spaced apart from each other, and extending in the first direction, respectively.

4. The semiconductor device of claim 3, further comprising:
a seed layer including an oxide of a transition metal element on a side surface of the wall structure between each of respective adjacent pairs of the plurality of bridge patterns,
wherein the first 2D channel layer extends from the seed layer along a surface of each of the bridge patterns.

5. The semiconductor device of claim 4, wherein the first transition metal dichalcogenide includes the transition metal element.

6. The semiconductor device of claim 3, wherein the second 2D channel layer does not extend along an upper surface of an uppermost bridge pattern from among the plurality of bridge patterns.

7. The semiconductor device of claim 1, wherein a thickness of the first 2D channel layer and a thickness of the second 2D channel layer are different from each other.

8. The semiconductor device of claim 1, wherein the wall structure further separates the first gate structure and the second gate structure from each other.

9. The semiconductor device of claim 1, further comprising:
a first insulating pattern extending in the first direction between the substrate and the first active pattern; and
a second insulating pattern extending in the first direction between the substrate and the second active pattern.

10. The semiconductor device of claim 1, wherein the first region is an NFET region, and the second region is a PFET region.

11. A semiconductor device comprising:
a substrate;
a wall structure extending in a first direction on the substrate;
a first sheet pattern extending in the first direction on an upper surface of the substrate and a side surface of the wall structure;
a second sheet pattern extending in the first direction on an upper surface of the first sheet pattern and the side surface of the wall structure;
a seed layer including a transition metal element on the side surface of the wall structure between the first sheet pattern and the second sheet pattern;
a two-dimensional (2D) channel layer extending from the seed layer along a surface of the first sheet pattern and a surface of the second sheet pattern, the 2D channel layer including a transition metal dichalcogenide including the transition metal element; and
a gate structure intersecting the first sheet pattern and the second sheet pattern, and the gate structure on the 2D channel layer.

12. The semiconductor device of claim 11, wherein the 2D channel layer has a single crystal structure.

13. The semiconductor device of claim 11, wherein the transition metal element includes at least one of molybdenum (Mo) or tungsten (W).

14. The semiconductor device of claim 13, wherein the transition metal dichalcogenide includes at least one of molybdenum disulfide (MoS₂) or tungsten disulfide (WS₂).

15. The semiconductor device of claim 11, wherein
the gate structure includes a gate dielectric film and a gate electrode sequentially stacked on the 2D channel layer,
the 2D channel layer does not extend along an upper surface of the second sheet pattern, and
the gate dielectric film extends along the upper surface of the second sheet pattern.

16. A semiconductor device comprising:
a substrate including a first region and a second region;
a first active pattern including a plurality of first bridge patterns sequentially stacked on the first region, spaced apart from each other, and extending in a first direction, respectively;
a second active pattern including a plurality of second bridge patterns sequentially stacked on the second region, spaced apart from each other, and extending in the first direction, respectively;
a wall structure extending in the first direction between the first region and the second region and separating the first active pattern and the second active pattern from each other;
a first seed layer including an oxide of a transition metal element on a first side surface of the wall structure between each of respective adjacent pairs of the plurality of first bridge patterns;
a first two-dimensional (2D) channel layer extending from the first seed layer along a surface of each of the first bridge patterns, the first 2D channel layer including a first transition metal dichalcogenide including the transition metal element;
a first gate structure intersecting each of the first bridge patterns and on the first 2D channel layer;
a second seed layer including the oxide of the transition metal element on a second side surface of the wall structure between the plurality of second bridge patterns;
a second 2D channel layer extending from the second seed layer along a surface of each of the second bridge patterns, the second 2D channel layer including a second transition metal dichalcogenide including the transition metal element; and
a second gate structure intersecting each of the second bridge patterns and on the second 2D channel layer.

17. The semiconductor device of claim 16, wherein each of the first 2D channel layer and the second 2D channel layer has a single crystal structure.

18. The semiconductor device of claim 16, wherein
the first 2D channel layer does not extend along an upper surface of a first uppermost bridge pattern from among the plurality of first bridge patterns, and
the second 2D channel layer does not extend along an upper surface of a second uppermost bridge pattern from among the plurality of second bridge patterns.

19. The semiconductor device of claim 16, wherein a thickness of the first 2D channel layer and a thickness of the second 2D channel layer are different from each other.

20. The semiconductor device of claim 16, wherein the first region is an NFET region, and the second region is a PFET region.
